(19) United States
(12) Patent Application Publication
(10) Pub. No.: US 2018/0074090 A1
(43) Pub. Date: Mar. 15, 2018

(54) MULTIPLE DEGREE OF FREEDOM MEMS SENSOR CHIP AND METHOD FOR FABRICATING THE SAME

(71) Applicant: Motion Engine Inc., Montreal (CA)

(72) Inventor: Robert Mark Boysel, Montreal (CA)

(21) Appl. No.: 15/558,807

(22) PCT Filed: Mar. 17, 2016
(86) PCT No.: PCT/CA2016/050303

§ 371 Date: Sep. 15, 2017

Related U.S. Application Data
(60) Provisional application No. 62/134,832, filed on Mar. 18, 2015.

(51) Int. Cl. G01P 15/097; G01P 15/08; G01P 15/125; G01C 19/574; G01C 19/5712; G01C 19/5769; B81B 7/00; B81C 1/00; G01L 9/00

(52) U.S. Cl. CPC G01P 15/097; G01P 15/0802; G01P 15/125; G01C 19/574; G01C 19/5712; G01C 19/5769; B81B 2201/0292; B81C 1/00238; B81C 1/00309; G01L 9/0045; B81B 2201/0235; B81B 2201/0242; B81B 2201/0264; B81B 7/0061

(57) ABSTRACT

A single Micro-Electro-Mechanical System (MEMS) sensor chip is provided, for measuring multiple parameters, referred to as multiple degrees of freedom (DOF). The sensor chip comprises a central MEMS wafer bonded to a top cap wafer and a bottom cap wafer, all three wafer being electrically conductive. The sensor comprises at least two distinct sensors, each patterned in the electrically conductive MEMS wafer and in at least one of the top and bottom cap wafer. Insulated conducting pathways extend from electrical connections on the top or bottom cap wafers, through at least one of the electrically conductive top cap and bottom cap wafers, and through the electrically conductive MEMS wafer, to the sensors, for conducting electrical signals between the sensors and the electrical connections. The two or more distinct sensors are enclosed by the top and bottom cap wafers and by the outer frame of MEMS wafer.

### TECHNICAL FIELD

The general technical field relates to Microelectromechanical Systems (MEMS)

Packaging, and more particularly to a method of fabricating a MEMS sensor with a hermetic package using Silicon-on-Insulator (SOI) wafers.

### BACKGROUND

Micro-electro-mechanical systems (MEMS) are an increasingly important enabling technology. MEMS inertial sensors are used to sense changes in the state of motion of an object, including changes in position, velocity, acceleration or orientation, and encompass devices such as accelerometers, gyroscopes, vibrometers and inclinometers. Broadly described, MEMS devices are integrated circuits (ICs) containing tiny mechanical, optical, magnetic, electrical, chemical, biological, or other, transducers or actuators. MEMS devices can be manufactured using high-volume silicon wafer fabrication techniques developed over the past fifty years for the microelectronics industry. Their resulting small size and low cost make them attractive for use in an increasing number of applications in a broad variety of industries including consumer, automotive, medical, aerospace, defense, green energy, industrial, and other markets.

MEMS devices, in particular inertial sensors such as accelerometers and angular rate sensors or gyroscopes, are being used in a steadily growing number of applications. As the number of these applications grow, the greater the demand to add additional functionality and more types of MEMS into a system chip architecture. Due to the significant increase in consumer electronics applications for MEMS sensors such as optical image stabilization (OIS) for cameras embedded in smart phones and tablet PCs, virtual reality systems and wearable electronics, there has been a growing interest in utilizing such technology for more advanced applications which have been traditionally catered to by much larger, more expensive and higher grade non-MEMS sensors. Such applications include single- and multiple-axis devices for industrial applications, inertial measurement units (IMUs) for navigation systems and attitude heading reference systems (AHRS), control systems for unmanned air, ground and sea vehicles and for personal indoor GPS-denied navigation. These applications also may include healthcare/medical and sports performance monitoring and advanced motion capture systems for next generation virtual reality. These advanced applications often require lower bias drift and higher sensitivity specifications well beyond the capability of existing consumer-grade MEMS inertial sensors on the market. In order to expand these markets and to create new ones, it is desirable and necessary that higher performance specifications be developed. It is also necessary to produce a low cost and small size sensor and/or MEMS inertial sensor-enabled system (s).

Given that MEMS inertial sensors such as accelerometers and gyroscopes are typically much smaller than traditional mechanical gyroscopes, they tend to be subject to higher mechanical noise and drift. Also, since position and attitude are calculated by integrating the acceleration and angular rate data, respectively, noise and drift lead to growing errors. Consequently, for applications requiring high accuracy, such as navigation, it is generally desirable to augment the six-degrees-of-freedom (6DOF) inertial capability of MEMS motion sensors (i.e., three axes of acceleration and three axes of angular rotation) with other position- and/or orientation-dependent measurements. Typically in the sensor industry, each measurement, whether (acceleration, angular rate, pressure, magnetic field) is referred to as a “degree-of-freedom”. Such multiple-degrees-of-freedom (MDOF) sensor fusion is necessary for better results. As an example, barometric pressure measurements can provide altitude information which can be used as a check against MEMS drift in order to “re-zero” the error. Three-axis magnetic field sensors can provide an additional compass function by measuring the sensor's orientation relative to the Earth's magnetic field.

Typically, these additional MEMS sensors are hybridly integrated with the inertial sensor. That is, a separately purchased or fabricated sensor chip is adhesively attached to an inertial sensor chip or its sensing integrated circuit (IC), or to a separate package substrate. The sensors are wire bonded to the packaging substrate and the package is sealed. Such a hybrid configuration generally introduces additional material (e.g., additional MEMS chips, adhesives, bond wires) and fabrication (e.g., die attach and wire bonding) costs.

There is thus a need for an improved MDOF MEMS sensor.

### SUMMARY

In accordance with possible embodiments, a MEMS sensor chip, a fabrication method, and a method of operating a MEMS sensor chip are provided. According to an aspect, the multiple degree-of-freedom (MDOF) sensor chip is a single chip that includes at least two distinct sensors enclosed or encapsulated therein. The single MEMS chip includes a top cap wafer, a central MEMS wafer and a bottom cap wafer with at least two distinct sensors integrated therein. For example, the single MEMS chip can enclose an inertial sensor and an additional or auxiliary sensor built directly into the same top cap wafer, central MEMS wafer and bottom cap wafer, thereby eliminating the need to purchase, attach, and wire bond separate chips.

According to a possible embodiment, a single Micro-Electro-Mechanical System (MEMS) sensor chip for measuring multiple parameters, referred to as multiple degrees of freedom (DOF) is provided. The sensor chip comprises an electrically conductive MEMS wafer, an electrically conductive bottom cap wafer and an electrically conductive top cap wafer. The MEMS wafer has first and second sides and an outer frame. The top cap wafer has an inner top cap side and an outer top cap side, the inner top cap side being bonded to the first side of the MEMS wafer. The bottom cap wafer has an inner bottom cap side and an outer bottom cap side, the inner bottom cap side being bonded to the second side of the MEMS wafer. At least one of the outer top cap side and the outer bottom cap side has electrical connections. The single MEMS sensor chip includes at least two distinct sensors, each patterned in the electrically conductive MEMS wafer and in at least one of the top and bottom cap wafer. The sensors are operative to sense at least two distinct parameters, respectively, along at least one of mutually orthogonal X, Y and Z axes. Insulated conducting pathways extend from the electrical connections, through at least one of the electrically conductive top cap and bottom cap wafers, and through the electrically conductive MEMS wafer, to the distinct sensors, for conducting electrical signals between the sensors and the electrical connections. The sensors are enclosed or encapsulated by the electrically conductive top and bottom cap wafers and by the outer frame of the electrically conductive MEMS wafer. The outer frame of the central MEMS wafer comprises the external lateral walls formed after dicing of the stacked top, central and bottom wafers.

The two or more distinct sensors can include any combination of: a 3-DOF accelerometer, a 3-DOF angular rate sensor, a pressure sensor and a magnetometer or any other sensor that can be patterned in the top cap, MEMS and bottom cap wafers forming the single MDOF MEMS sensor chip.

In an exemplary embodiment, the MDOF sensor chip includes at least one inertial sensor and at least one other sensor patterned in one or more of the top, MEMS or bottom cap wafers. The other sensor(s) can be referred to as auxiliary sensor(s), and can include inertial or non-inertial sensor(s). However, it is to be noted that, in some embodiments, the MDOF sensor chip need not include an inertial sensor. By way of example, and without limitation, an embodiment of the MDOF sensor could include a magnetometer (e.g., a 3DOF magnetometer) and a pressure sensor, as described further below, without any inertial sensor.

In an exemplary embodiment, the bottom, top and MEMS wafer are silicon-based wafers, and the MEMS wafer is preferably a silicon-on-insulator (SOI) wafer. It is also possible for the top and bottom cap wafers to be made of SOI wafers.

According to a possible embodiment, both the bottom cap wafer and the top cap wafer may comprise electrical contacts on or over their respective outer cap sides, in electrical contact with the insulated conducting pathways. Advantageously, different types of sensors can be encapsulated in the top, MEMS and bottom layers of a single MDOF sensor chip, eliminating any wire bonding.

According to a possible embodiment, the single MEMS sensor chip includes an inertial sensor comprising one or more MEMS movable or resonant structures, typically including a large proof mass formed in most or all of the thickness of the MEMS wafer. The MEMS wafer, the top cap wafer and the bottom cap wafer define a cavity for housing the proof mass(es). Proof mass(es) and springs are patterned in the MEMS wafer layer, with the springs suspending the proof mass(es) in their respective cavity(ies). Associated with each proof mass are electrodes, operatively coupled to the proof mass. The electrodes are typically provided in at least one of the top and bottom cap wafers, and also possibly in portions of the MEMS wafer surrounding the proof mass. The electrodes are preferably patterned in the wafer layers of the MDOF sensor, and defined by trenches that can be filled or at least lined with an insulating material.

The inertial sensor can include accelerometer(s) or angular rate sensor(s) or preferably a combination of both. The accelerometer preferably comprises a single proof mass and its associated electrodes, which are preferably located in the top and bottom cap wafers, facing the proof mass. It is possible that the accelerometer includes more than one proof mass, provided in the same or in distinct cavities.

The angular rate sensor preferably comprises a first in-plane 2DOF sensor, also referred to as XY angular rate sensor, and a second out-of-plane 1DOF sensor, also referred to as Z angular rate sensor. According to a possible embodiment, the in-plane angular rate sensor comprises two proof masses, with corresponding electrodes. According to a possible embodiment, the Z angular rate sensor also comprises two proof masses, with corresponding electrodes. However, in other possible embodiments, it can be considered to use a single proof mass to for the angular rate sensor.

According to a possible embodiment, the MDOF sensor includes other or auxiliary sensors in addition to the inertial sensor, such as pressure sensor(s), magnetometer(s), and the like. The other sensors can each include a MEMS structure which is preferably patterned in the MEMS wafer, and electrodes operatively coupled to the MEMS structure, and preferably patterned in the top and/or bottom cap wafers. The MEMS structure can include for example membranes, strips, rods and the likes, which may or not move in response to a change in the environment of the MDOF sensor.

In an exemplary embodiment, the pressure sensor can include a membrane patterned in the MEMS wafer, and electrodes patterned in the top cap wafer, facing the membrane. The pressure sensor can include a recess and a cavity, the membrane separating the recess and cavity. Movement of the membrane in response to a change of pressure in one of the recess or cavity is detected by the electrodes, which face the membrane. Preferably, the electrodes and recess are patterned in the top cap wafer. The membrane and the cavity are formed in the MEMS wafer, and the bottom cap wafer closes the cavity. Still preferably, the pressure sensor is a differential pressure sensor, with two identical pressure sensors as described above.

In an exemplary embodiment, the magnetometer includes three 1DOF magnetometer sensors, with two in-plane or X and Y magnetometers and one out-of-plane or Z magnetometer. The two in-plane magnetometers can include resonant membranes, for example a pair of strips, each pair aligned with the X and Y axis respectively. The in-plane magnetometer comprise electrodes, preferably provided in the top cap wafer, and operatively coupled to the strips, to detect motion of the strips along the Z axis, indicative of a component of a magnetic field along the X or Y axis. The out-of-plane magnetometer can include a comb sensor or comb structure to detect a motion of the comb sensor along one of the X or Y axis, indicative of a component of a magnetic field along the Z axis. In use, alternating current is injected in the X, Y and Z magnetometers, such that a Lorentz force will act on the strips and/or comb structure in response to a magnetic field (\vec{F_{L}}=I\vec{L}×\vec{B}).

Alternatively, a single 3DOF magnetometer can be fabricated within the top, MEMS and bottom cap wafers, to detect X, Y and Z components of a magnetic field.

According to an exemplary embodiment, the MDOF is a 10DOF sensor, with:
a 3 DOF accelerometer, including one proof mass and associated electrodes, operable to detect acceleration along mutually orthogonal X, Y and Z axes,
a 2 DOF in-plane or XY angular rate sensor, including two proof masses and associated electrodes, operable to detect angular rate along the X and Y axis upon driving the respective proof masses in Z, the proof masses being driven out-of-phase one relative to the other;
a 1 DOF out-of-plane Z angular rate sensor, including two proof masses and associated electrodes, operable to detect angular rate along the Z axis upon rocking the respective proof masses about the X and Y axis, respectively;
a 1 DOF pressure sensor as described above; and
a 3 DOF magnetometer as described above.

According to another exemplary embodiment, the MDOF sensor is a 9DOF sensor, with a 3DOF accelerometer, a 3DOF gyroscope, and a 3DOF magnetometer as described above. According to yet another exemplary embodiment, the MDOF sensor is a 7DOF sensor, with a 3DOF accelerometer, a 3DOF gyroscope, and a 1DOF pressure sensor as described above. According to yet another embodiment, the MDOF sensor is a low power gyroscope comprising a 3DOF accelerometer and a 3DOF magnetometer.

As can be appreciated, the proposed architecture for the MDOF sensor allows measuring different physical quantities having different mechanical requirements, and thus having different design and fabrication requirements, in a single encapsulated sensor.

### BRIEF DESCRIPTION OF THE DRAWINGS

It is noted that the appended drawings illustrate only exemplary embodiments of the invention and are, therefore, not to be considered limiting of its scope, for the invention may admit to other equally effective embodiments.

FIG. 1A is perspective view of a single MDOF MEMS sensor chip, in accordance with an exemplary embodiment;

FIG. 1B is a plan view of the single MDOF MEMS sensor chip of FIG. 1, showing different cross-sectional lines, along which the following cross-sectional views are taken.

FIG. 2 is an exploded perspective view of the single MDOF MEMS sensor chip of FIGS. 1A and 1B.

FIG. 3A is a cross-sectional view of the single MDOF MEMS sensor chip of FIG. 1B, taken along line 3A-3A, showing a possible embodiment of an in-plane or XY angular rate sensor, with two proof masses shown in one possible position.

FIG. 3B is a partial cross-sectional view of the single MDOF MEMS sensor chip of FIG. 1B, taken along line 3B-3B, showing a possible embodiment of a pressure sensor.

FIG. 3C is a partial cross-sectional view of the single MDOF MEMS sensor chip of FIG. 1A, taken along lines 3C-3C, showing a possible embodiment of a 1DOF magnetometer, adapted to detect a component of a magnetic field along an out-of-plane or Z axis.

FIG. 3D is a partial cross-sectional view of the single MDOF MEMS sensor chip of FIG. 1A, taken along lines 3C-3C, showing a possible embodiment of a 1DOF magnetometer, adapted to detect a component of a magnetic field along an in-of-plane or X or Y axis.

FIG. 4 is a cross-sectional view of the single MDOF MEMS sensor chip of FIG. 1A, taken along lines 4-4, showing a possible embodiment of a 3DOF accelerometer.

FIG. 5 is a cross-sectional view of the single MDOF MEMS sensor chip of FIG. 1B, taken along line 5-5, showing a possible embodiment of an in-plane or XY angular rate sensor, with two proof masses shown out-of-phase one relative to the other.

FIGS. 6A and 6B are two partial cross-sectional views of the single MDOF MEMS sensor chip of FIG. 1A, taken along lines 6A-6A and 6B-6B, respectively, showing the proof masses of the in-plane or XY angular rate sensor.

FIG. 7 is a cross-sectional view of the single MDOF MEMS sensor chip of FIG. 1B, taken along line 7-7, showing a possible embodiment of an out-of-plane or Z angular rate sensor, with two proof masses shown out-of-phase one relative to the other.

FIGS. 8A and 8B are two partial cross-sectional views of the single MDOF MEMS sensor chip of FIG. 1A, taken along lines 8A-8A and 8B-8B, respectively, showing the proof masses of the out-of-plane or Z angular rate sensor.

FIG. 9A is a partial exploded view of the single MDOF MEMS sensor chip of FIG. 1B, showing a possible embodiment of a pressure sensor, in this case a differential pressure sensor.

FIG. 9B is a partial cross-sectional view of the single MDOF MEMS sensor chip of FIG. 1B, taken along lines 9B-9B, showing the differential pressure sensor.

FIG. 10A is a partial exploded view of the single MDOF MEMS sensor chip of FIGS. 1 and 1B, showing a possible embodiment of a Z-axis magnetometer.

FIG. 10B is a partial exploded view of the single MDOF MEMS sensor chip of FIGS. 1 and 1B, showing a possible embodiment of a X-axis or Y-axis magnetometer.

FIG. 10C is a partial cross-sectional view of the Z-axis magnetometer of FIG. 10A, taken along lines 10C-10C, showing the Z-axis magnetometer.

FIG. 10D is a partial cross-sectional view of the X or Y-axis magnetometer of FIG. 10B, taken along lines 10D-10D, showing X-axis or Y-axis magnetometer.

FIG. 11A is an enlarged view of the X-axis or Y-axis magnetometer of FIG. 10B.

FIG. 11B is a cross-sectional view of the X-axis or Y-axis magnetometer of FIG. 11A, taken along line 11B-11B.

FIG. 12 is a partial plan view of the comb structure of the Z-axis magnetometer of FIG. 10A, with the top cap wafer removed.

FIG. 13A and 13B are enlarged views of the comb structure of the Z-axis magnetometer, shown in two different positions.

FIGS. 14A to 14H are cross-sectional views showing the different steps for manufacturing a single MDOF MEMS sensor chip as shown the preceding Figures, according to a possible embodiment. FIG. 14I shows an optional step where an IC wafer is bonded at the wafer-level to single MDOF MEMS sensor chips, prior to dicing. FIG. 14J is a cross-sectional view of a MDOF sensor system bonded to a PCB.

### DETAILED DESCRIPTION

In the following description, similar features in the drawings have been given similar reference numerals, and, in order to preserve clarity in the drawings, some reference numerals may be omitted when they were already identified in a preceding figure. It should also be understood that the elements of the drawings are not necessarily depicted to scale, since emphasis is placed upon clearly illustrating the elements and structures of the present embodiments.

Embodiments of a MDOF MEMS Sensor

In accordance with a possible embodiment, there is provided a multiple-degrees-of-freedom MDOF MEMS sensor chip. The exemplary sensor is a 10 DOF sensor including a three-axis accelerometer, a three-axis gyroscope (or angular rate sensor), a three-axis magnetometer, and a pressure sensor, since these are representative of the sensors desired in state of the art navigation units. However, the sensor integration approach described is of more general applicability to other types of MEMS sensors and could include microphones, ultrasonic transducers, thermometers, and the like.

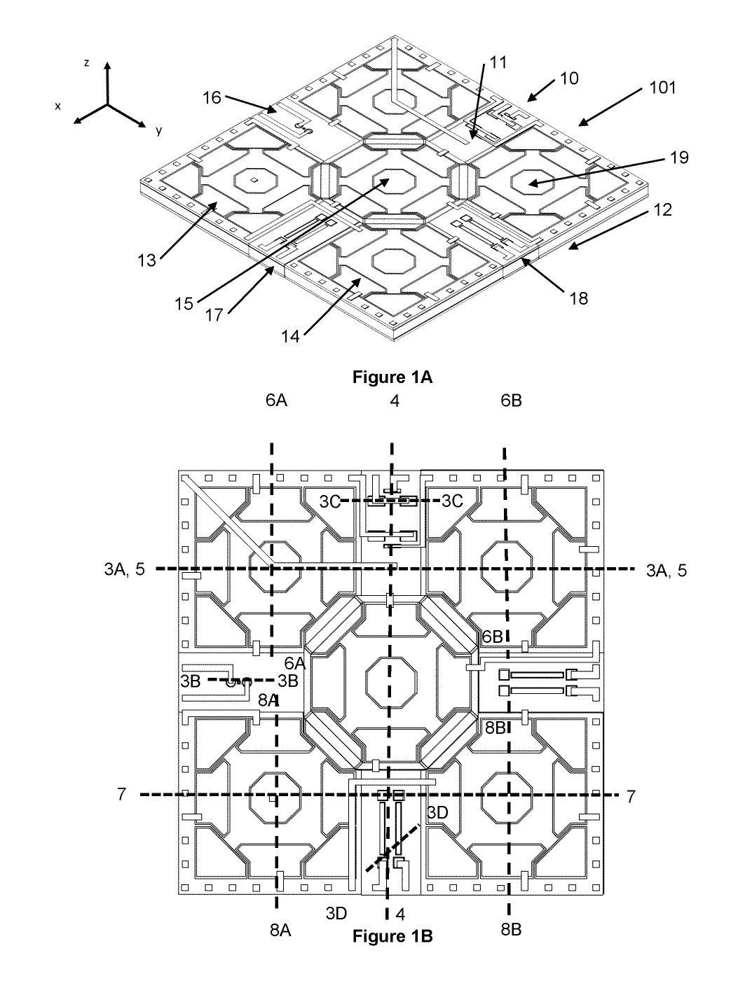

FIG. 1A shows an exemplary embodiment of a 10 DOF MEMS inertial sensor chip 10 fabricated using fabrication techniques described herein. The single 10 DOF sensor chip 10 includes two angular rate sensors 11, 12 which form together a 2 DOF X/Y axes gyroscope; two angular rate sensors 13, 14 which form a Z axis gyroscope; a 3 axis accelerometer 15, a pressure sensor 16, Y and X axis magnetic sensors 17, 18, and a Z axis magnetic sensor 19.

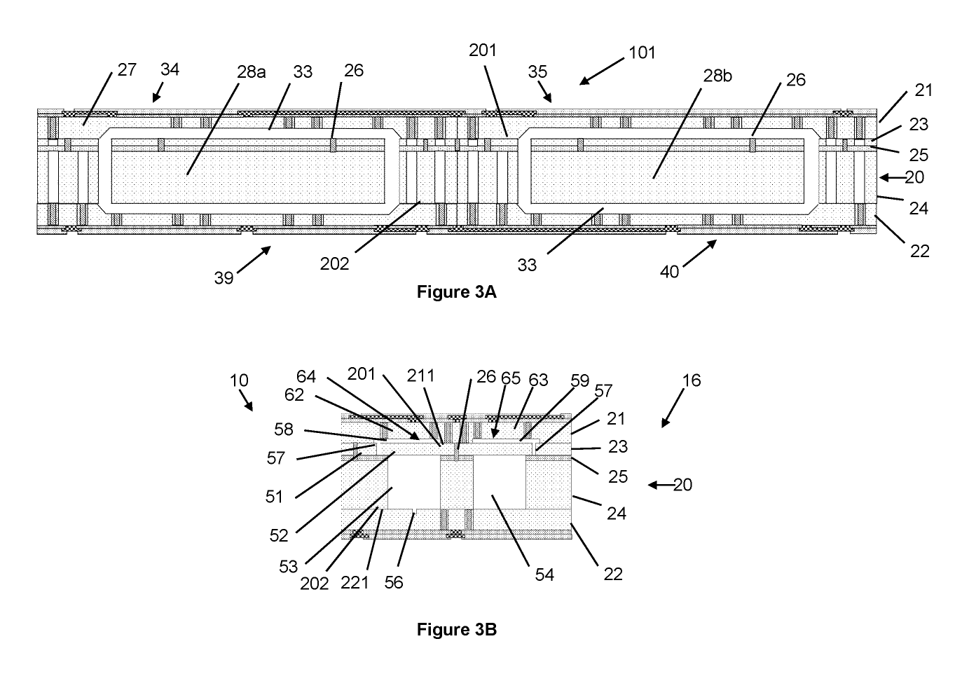

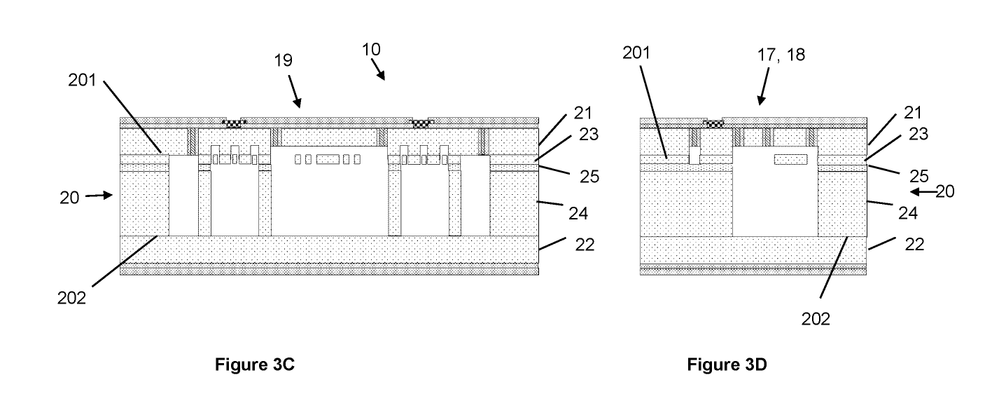

FIG. 1B is a top view of the multi-DOF MEMS sensor chip showing the lines along which cross-sections are shown in FIGS. 3-8. The lines are labeled according to the corresponding cross-section.

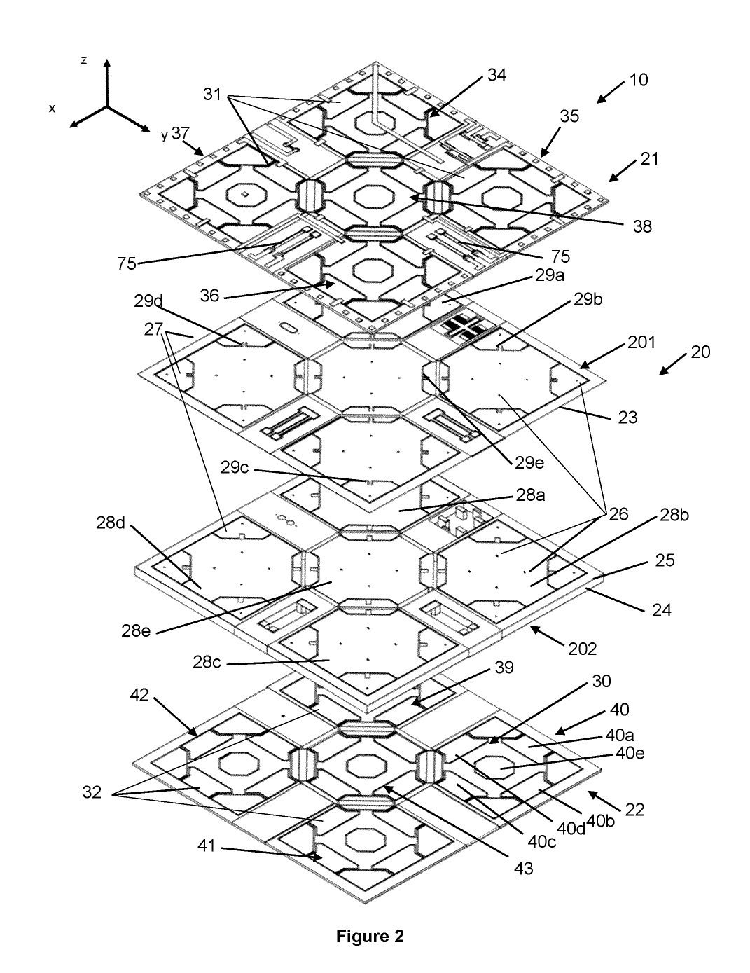

FIG. 2 shows an exploded isometric view of the same MDOF sensor as in FIGS. 1 and 1B. FIGS. 3A-C show cross sectional views through the sensors 11, 12 and 16-19 in FIG. 1B along lines 3A, 3B, 3C, and 3D to illustrate the similarities in construction. Since the individual Y and X magnetometers 17 and 18 are identical but rotated by 90 degrees, only the cross-section of the Y magnetometer 17 is illustrated in FIG. 3D. The sensor chip 10 includes a MEMS wafer 20 having opposed top and bottom sides 201, 202 (also referred as first and second sides 201, 202), and top and bottom cap wafers 21, 22 respectively bonded to the top and bottom sides 201, 202 of the MEMS wafer 20. The electrically conductive top cap wafer 21 has an inner side, conductively bonded in specific regions to the first or top side of MEMS wafer 20, and an outer side, provided with electrical contacts. Similarly, the electrically conductive bottom cap wafer 22 has an inner side, conductively bonded in specific regions to the second or bottom side of MEMS wafer 20, and an outer side, which may or not be provided with electrical contacts. Of course, it is possible to provide the electrical contacts only on the bottom cap wafer, instead of on the top cap wafer. The

MEMS wafer 20 can be a SOI wafer including a device layer 23, a handle layer 24 under and spaced from the device layer 23, and an insulating layer 25 (e.g., buried oxide) sandwiched between the device and handle layers 23, 24. In the illustrated embodiment, the top cap wafer 21 is bonded to and in electrical contact with selected portions of the device layer 23, while the bottom cap wafer 22 is bonded to and in electrical contact with selected portions of the handle layer 24. The device layer 23 and the handle layer 24 of the MEMS wafer 20, as well as the top and bottom cap wafers 21, 22 are made of electrically conductive material such as, for example, a silicon-based semiconductor material. The insulating layer 25 acts to insulate the top half of the sensor 10 from the bottom half. In some implementations, electrical shunts 26 can be formed through the insulating layer 25 to allow electrical connections to be established between the device layer 23 and the handle layer 24 at desired places. The SOI wafer typically consists of a thin (e.g., 1-100 microns) device or single crystal silicon (SCS) layer 23 over a thin (e.g., 1-2 microns) insulating buried oxide layer 24, both supported by a thick (e.g., 100-700 microns) handle layer 25, which is also made of silicon.

Still referring to FIG. 2, each of the distinct sensors (accelerometer, angular rate sensor, pressure sensor, and magnetometer) built in the MEMS sensor chip have sensing and/or resonant structures patterned in at least two of the layers forming the chip, and for some of the sensors, they have MEMS sensing and/or driving structures patterned in all three layers, i.e. in the top, bottom and MEMS layers 21, 20, 22. Preferably, for embodiments in which the electrical connections are provided on or over the top cap wafer, electrodes associated with a given sensor are patterned in at least the top cap wafer, as well as in the MEMS wafer layer. The MEMS wafer layer includes the resonant or movable structure used to sense a variation in a parameter, such as acceleration, rotation, pressure, electric field, etc. The resonant or movable structure are also provided with one or more electrodes patterned therein. For some of the sensors, electrodes are also patterned in the bottom cap wafer. Insulating conducting pathways extend from each of the electrodes in the bottom cap, in the MEMS and the top cap wafers, to the electrical contacts on top cap wafer. In some embodiments, electrical contacts are also provided on the bottom cap wafer. In this case, insulating conducting pathways can connect at least some of the electrodes of the sensors to the electrical contacts on the bottom cap. An insulated conducting pathway comprises conducting material passing in or through the wafer layers, that is insulated from the remainder of the conductive wafer material. The “conducting material” of the pathway can be a conductive material, deposited in a hole or via etched in the wafer, or it can consist of plug of silicon wafer, surrounded by a closed-loop trench. Depending on where it is located in the sensor, the trench can be left empty or be filled with an insulating material. An insulated conducting pathway can extend “vertically”, i.e. along the Z axis of the chip, as well as “horizontally”, i.e. in the X-Y plane of the chip. For example, a portion of a pathway can consist of a plug of silicon extending vertically in the top cap wafer, and another portion of the pathway can consist of a lead patterned in the plane of the MEMS wafer. The different portions of the pathway extending in the MEMS sensor chip connect at the interface of the top and MEMS wafer layer, and/or at the interface of the bottom and MEMS wafer layer. As can be appreciated, the different elements (electrodes, leads, movable/flexible structures) forming the different MEMS sensors are built in the layers of the chip, with the movable/flexible structures encapsulated by the outer frame or sidewalls of the MEMS wafer 20, and with the top and bottom cap wafers 21, 22 not only protecting these movable structures, but also having a functional role since they integrate electrodes, leads and electrical connections. Since the electrodes, resonant and/or movable structures and insulated conducting pathways can extend and be formed along any of X, Y and Z axis, the single MDOF MEMS sensor chip can be referred to as a three-dimensional (3D) MDOF sensor chip.

Inertial Sensor Description

Referring to FIGS. 1A, 2 and 3A, a possible embodiment of an inertial sensor 101 is shown. In the embodiment, the inertial sensor 101 includes a frame structure 27, a plurality of proof masses 28a to 28e, and a plurality of spring assemblies 29a to 29e. Each spring assembly 29a to 29e suspends a corresponding one of the proof masses 28a to 28e from the frame structure 27 and enables the corresponding one of the proof masses to move along mutually orthogonal first, second and third axes, designated as the z, x and y axes, respectively, and will be so referred to herein. In particular, in the exemplary embodiment of FIGS. 1 to 3, the x and y axes may be referred to as “in-plane”, “lateral” or “horizontal” directions, while the z axis may be referred to as an “out-of-plane”, transverse” or “vertical” direction. The frame structure 27 can comprise sidewalls formed in the top, MEMS and bottom wafers 21, 20, 22 that define the cavities in which the proof masses are respectively suspended. In this example, the frame structure includes corner posts patterned in the wafers, the springs extending from the corner posts to the proof masses.

Also, throughout the present description, terms such as “top” and “bottom”, “above” and “below”, “over” and “under”, “upper” and “lower”, and other like terms indicating the position of one element with respect to another element are used herein for ease and clarity of description, as illustrated in the figures, and should not be considered limitative. It will be understood that such spatially relative terms are intended to encompass different orientations of the MEMS sensor chip in use or operation, in addition to the orientation exemplified in the figures. In particular, the terms “top” and “bottom” are used to facilitate reading of the description, and those skilled in the art of MEMS will readily recognize that, when in use, the MEMS sensor chip can be placed in different orientations such that, for example, the top and bottom cap wafers are positioned upside down. It will further be understood that the term “over” and “under” in specifying the spatial relationship of one element with respect to another element denotes that the two elements are either in direct contact with or separated by one or more intervening elements.

In the illustrated embodiment, the proof masses are large and heavy proof masses, in contrast with thin masses fabricated in parallel with the comb electrodes typically used in “2D” motion sensors. In the present embodiment, the MEMS wafer is an SOI (silicon-on-insulator) wafer, comprising an insulating layer 25 sandwiched between a handle layer 24 and a device layer 23. The bulk of the proof masses 28 are in the handle layer 24 of the SOI wafer 20, and the springs 29 are patterned in the device layer 23. In this particular embodiment, the spring assemblies 29a-29d associated with the respective proof masses 28a-28e include four springs in the form of thin strips patterned in the device layer 23. The caps 21, 22 include one or more recesses 30 which form the capacitor gap between the electrodes 31, 32 and the outer surfaces of the proof mass 28. Drive and sense capacitors are formed across the gap between the outer surfaces of the proof masses 28 and the inner surfaces of the caps 21, 22. In other embodiments, it can be considered to use a stack of conductive wafers bonded to one another instead of the SOI wafer for the central MEMS layer.

Referring still to FIG. 3A, the top cap wafer 21, bottom cap wafer 22, and frame structure 27 define, when bonded together, one or more cavities 33, or chambers, each of which encloses one or more of the proof masses 28a to 28e, such that each proof mass is enclosed within a cavity 33. In some embodiments, the pressure in each cavity 33 can be adjusted independently. In particular, in some embodiments, the proof masses used for angular rate measurement are advantageously enclosed in respective vacuum cavities. For example, in the illustrated embodiment, the cavities 33 enclosing the first, second, third and fourth proof masses 28a to 28d, which are used for angular rate measurements, can be hermetically sealed vacuum cavities, which may not be the case for the fifth proof mass 28e used for linear acceleration measurements. Also, although each proof mass is enclosed its own cavity in FIGS. 2 and 3A, in other embodiments, the number of cavities may be less than the number of proof masses. In particular, the number and arrangement of the cavities may be dictated by environmental (e.g., high or low pressure) and/or mechanical (e.g., support integrity) considerations.

Referring still to FIGS. 2 and 3A, the MEMS motion sensor 101 also includes top and bottom electrode assemblies 34, 35, 36, 37, 38, 39, 40, 41, 42, 43 respectively provided in the top and bottom cap wafers 21, 22 and forming capacitors with the plurality of proof masses 28a to 28e. The top and bottom electrodes 34-43 are together configured to detect motions of the plurality of proof masses, namely linear accelerations along and angular rate about three mutually orthogonal axes. In some implementations, the top and bottom electrodes 34-43 form eight electrode arrangements, where each of the electrode arrangements includes at least one pair of electrodes. Each pair of electrodes can be composed of two of the top electrodes 34-38 or two of the bottom electrodes 39-43 or one each of the top and bottom electrodes 34-43.

It will be understood that the subdivision of the top and bottom electrodes 34-43 into such electrode arrangements is made from a functional or conceptual standpoint and that, in practice, a given “physical” top or bottom electrode 34-43 may be part of more than one electrode arrangement, and that the functions performed by two or more electrode arrangements may be performed by the same “physical” electrode 34-43 without departing from the scope of the present invention. In other words, an “electrode arrangement” or “electrode assembly” is a group of electrodes which are functionality related to drive the proof masses or to sense movement of the proof masses. Electrode arrangements or assemblies are reconfigurable according to the specific applications for which the MDOF sensor is to be used. Typically, electrodes are arranged in pairs. In non-inertial sensors, the electrodes can be arranged to detect motion of other types of MEMS structures, such as membranes and strips, as will be described later on in the description.

In the present embodiment of the single MEMS sensor chip, the inertial sensor 101 comprises an 3-DOF accelerometer, including a single proof mass 28e, as well as a 3-DOF angular rate sensor (or gyroscope), including four proof masses 28a-28d. In other embodiments of the MDOF MEMS sensor chip, the inertial sensor can comprise only one of the 3-DOF accelerometer and 3-DOF angular rate sensor.

3DOF Accelerometer

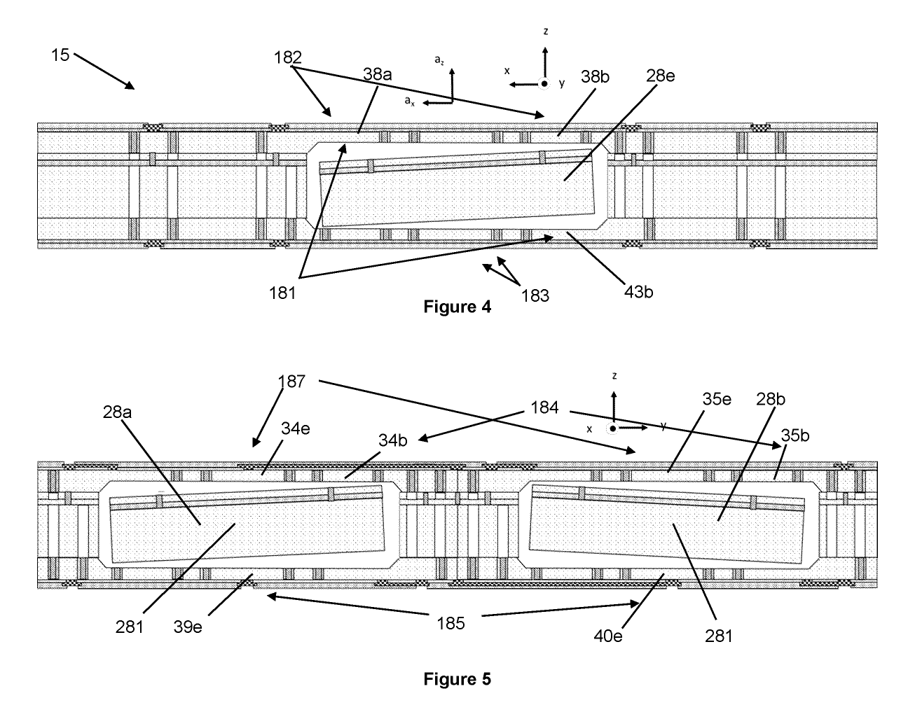

FIG. 4 is a cross-section taken along line 4-4 in FIG. 1B, showing the proof mass 28e in motion. The springs 29e which attach the proof mass to the outer frame structure 27 are not visible because line 4-4 do not pass through them. In order to provide three-axis linear acceleration sensing capabilities, the electrode arrangements can include first, second and third sensing electrode assemblies 181 to 183, each associated with one or more proof masses 28, to form the accelerometer 15. The electrodes of the accelerometer can be referred as accelerometer electrodes, to distinguish them from electrodes of the other sensors of the chip. In the embodiment of FIG. 4, the first, second and third sensing electrode assemblies 181 to 183 are each associated with the fifth proof mass 28e (which can also be referred to as the accelerometer proof mass) thus forming a 3-DOF accelerometer. In particular, the accelerometer proof mass 28e is configured to move vertically along the z axis in response to a z-directed acceleration and to rotate about the x and x axes in response to y- and x-directed accelerations, respectively. The first sensing electrode assembly 181 is configured to detect a translational motion of the fifth proof mass 28e along the z axis, the translational motion being indicative of a linear acceleration along the z axis. The second sensing electrode assembly 182 is configured to detect a rotation of the fifth proof mass 28e about the y axis, the rotation being indicative of a linear acceleration along the x axis. The third sensing electrode assembly 183 (not in the plane of this page) is configured to detect a rotation of the fifth proof mass 28e about the x axis, the rotation being indicative of a linear acceleration along the y axis. Of course, the number and arrangement of electrodes can vary depending on the application in which the MEMS motion sensor is to be used.

For this electrode configuration, the acceleration aₓ, a_{y} and a, can be determined using differential capacitance measurements. For example, by measuring the difference of the capacitance between the fifth proof mass 28e and the electrode 38a and the capacitance between the fifth proof mass 28e and the electrode 38b, the displacement of the fifth proof mass 28e along the z axis is subtracted out and aₓ can be measured. The acceleration component a_{y} can be obtained in a similar manner. Furthermore, by taking the difference between the capacitances measured by the electrode 38a and the electrode 43b, the displacement of the fifth proof mass 28e along the x axis is subtracted out and a, can be measured.

Angular Rate Sensor

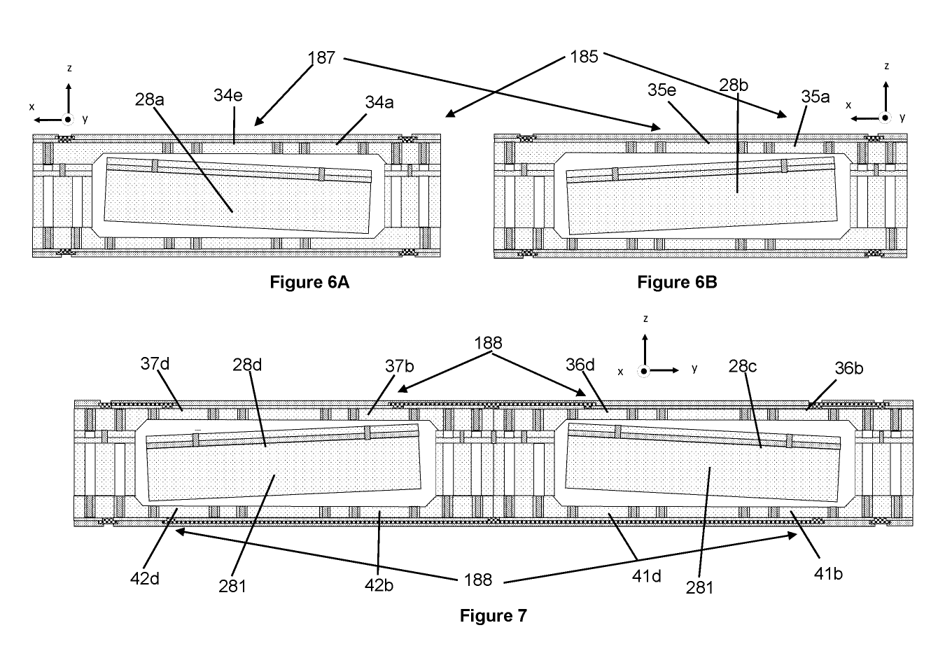

Referring to FIGS. 5, 6A and 6B, 7, and 8A and 8B, which are cross-sections along lines 5-5, 6A-6A, 6B, 7-A, 8A-8A and 8B-8B respectively in FIG. 1B, in order to provide three-axis angular rate sensing capabilities, the electrode assemblies 181 to 188 can include first and second driving electrode assemblies 187, 188 and fourth, fifth and sixth sensing electrode assemblies 184 to 186, each of these driving and sensing electrode assemblies 184 to 188 being associated with one or more angular rate sensor proof masses 28a,b,c,d. In the embodiment of FIGS. 5, 6A and B, 7, and 8A and B, the first driving and fourth and fifth sensing electrode assemblies 187, 184, 185 (not in the plane of the figure) are each associated with the second and third proof masses 28a, 28b, and are therefore used to measure in-plane angular rates about the x and y axes, thus forming the angular rate sensors 11, 12. Meanwhile, the second driving and sixth sensing electrode assemblies 188, 186 are each associated with the third and fourth proof masses 28c, 28d, and are therefore used to measure angular rates about the z axis. Electrode assemblies 186, 188 and proof masses 28c, 28d thus form the angular rate sensors 13, 14, in turn forming together the Z-axis gyroscope In the illustrated embodiment, the electrodes associated with the first driving electrode assembly 187 are located in corresponding above and below central regions 281 of the first and second proof masses 28a, 28b, while the electrodes associated with the second driving and fourth, fifth and sixth electrode assemblies 188, 184 to 186 are located above and below but laterally from the central regions of the first, second, third and fourth proof masses 28a to 28d. Of course, various other electrode arrangements could be used in other embodiments.

Referring to FIG. 5, the first driving electrode assembly 187 is configured to drive a vertical motion of each of the first and second proof masses 28a, 28b along the first axis at an out-of-plane drive frequency. For example, the drive signal can be a time-periodic sinusoidal signal. Depending on the application, the out-of-plane drive frequency may or not correspond to a resonant frequency of the resonant structures formed by each of the first and second proof masses 28a, 28b and their associated spring assemblies. In the illustrated embodiment, the first driving electrode 187 assembly is configured to drive the first proof mass 28a 180 degrees out-of-phase relative to the second proof mass 28b. For this purpose, the first driving electrode assembly 187 can include a pair of top driving electrodes 34e, 35e, one of which being located above a central region 281 of the first proof mass 28a and the other being located above a central region 281 of the second proof mass 28b, and a pair of bottom driving electrodes 39e, 40e, one of which being located below the central region 281 of the first proof mass 28a and the other being located below the central region 281 of the second proof mass 28b.

Referring still to FIG. 5, the fourth sensing electrode assembly 184 is configured to sense a Coriolis-induced, rocking motion of the first and second proof masses 28a, 28b along the y axis, which is indicative of an angular rate Ωₓ about the x axis. In the illustrated embodiment, the fourth sensing electrode assembly 184 forms first and second capacitors with the first and second proof masses 28a, 28b and measures a difference between a capacitance of the first capacitor and a capacitance of the second capacitor. The capacitance difference is indicative of the angular rate Q_{X} to be measured. To measure this capacitance difference, the fourth sensing electrode assembly 184 can include a pair of top sensing electrodes 34b, 35b disposed along a line parallel to the y axis, on similar sides of the top driving electrodes 34e, 35e. Of course, the number and arrangement of electrodes can vary depending on the application in which the MEMS motion sensor is to be used.

As the first and second proof masses 28a, 28b are driven vertically 180 degrees out-of-phase by the first driving electrode assembly 187, their respective Coriolis-induced, rocking motions along the y axis when subjected to angular rate about the x axis will also be 180 degrees out-of phase. It will be appreciated that by using two proof masses driven 180 degrees out of phase, the induced Coriolis accelerations of the two proof masses will also be 180 degrees out of phase, whereas any linear acceleration component will have the same effect on each mass. Thus when the signals from corresponding electrodes on the two masses are subtracted, any linear acceleration signals will cancel out.

In this regard, FIG. 5 depicts a snapshot in time of the first and second proof masses 28a, 28b at their maximum Coriolis amplitude displacement points.

Therefore, by synchronously measuring the difference in capacitances of electrodes on similar sides of the two proof masses 28a, 28b (e.g., 34b and 35b), the time-dependent capacitance change due to the angular rate around the x axis is obtained since the angular rate signals (C₀+/−ΔCC_{Coriolis}) on these two electrodes are of opposite sign while the static or low-frequency responses due to y and z acceleration

(C₀+ΔCₓ+ΔC_{z}), being of the same sign, are subtracted out. Of course, other electrode configurations involving or not differential capacitance measurements can be used in other embodiments.

It is to be noted that by proper selection or adjustment of the mechanical and/or geometrical properties of the first and second proof masses 28a, 28b and their associated spring assemblies, the resonant frequencies of the oscillation modes involved in the measurement of the angular rate Ωₓ about the x axis can be tailored to provide either matched or nearly matched resonance conditions between the driving and sensing modes, where the driving and sensing resonant frequencies of the driving and sensing modes are equal or close to each other, or unmatched resonance conditions between the driving and sensing modes, where driving and sensing resonant frequencies are substantially different from each other.

Referring back to FIGS. 6A and 6B, in a similar manner a fifth sensing electrode assembly 185 can be configured to sense a Coriolis-induced, rocking motion of the first and second proof masses 28a, 28b along the x axis, which is indicative of an angular rate Q_{y} about the y axis. In the illustrated embodiment, the fifth sensing electrode assembly 185 forms third and fourth capacitors with the first and second proof masses 28a, 28b and measures a difference between a capacitance of the third capacitor and a capacitance of the fourth capacitor. The capacitance difference is indicative of the angular rate Ω_{y} to be measured. To measure this capacitance difference, the fifth sensing electrode assembly 185 can include a pair of top sensing electrodes 34a, 35a disposed along lines parallel to the x axis, on similar sides of the top driving electrodes 34e, 35e. Of course, the number and arrangement of electrodes can vary depending on the application in which the MEMS motion sensor is to be used.

For this configuration of the fifth sensing electrode assembly 185, the angular rate Ω_{y} about the y axis can be determined using differential capacitance measurements involving the first and second proof masses 28a, 28b being driven 180 degrees out-of-phase from each other, as in FIG. 5 for Ωₓ. Of course, other electrode configurations involving or not differential capacitance measurements can be used in other embodiments. Also, like in the measurement of Ωₓ, the measurement of the angular rate Ω_{y} can be performed either with matched or nearly matched driving and sensing modes or with unmatched driving and sensing modes.

Referring now to FIG. 7, a cross-section along line 7-7 in FIG. 1B, it will be understood that for the illustrated embodiment of the MEMS motion sensor 10, the angular rate Ω_{z} around the z axis is to be measured differently than around the x and y axes since the drive axis has to be perpendicular to the axis about which the angular rate is to be sensed. Accordingly, in FIG. 7, the second driving electrode assembly 188 is configured to drive a rocking motion of each of the third and fourth proof masses 28c, 28d along the y axis at an in-plane drive frequency. In this regard, FIG. 7 depicts a snapshot in time of the driven third and fourth proof masses 28c, 28d at their maximum driven amplitude displacement points along the y axis. Depending on the application, the in-plane drive frequency may or not correspond to a resonant frequency of the resonant structures formed by each of the first and second proof masses 28c, 28d and their associated spring assemblies. In the illustrated embodiment, the second driving electrode assembly 188 is configured to drive the third proof mass 28c 180 degrees out-of-phase relative to the fourth proof mass 28d. For this purpose, the second driving electrode assembly 188 can include:
a first pair of top driving electrodes 36b, 36d disposed along a line parallel to y axis, above and laterally offset with respect to a central region 281 of the third proof mass 28c;
a second pair of top driving electrodes 37b, 37d disposed along a line parallel to the y axis, above and laterally offset with respect to a central region 281 of lo the fourth proof mass 28d;
a first pair of bottom driving electrodes 41b, 41d disposed along a line parallel to y axis, below and laterally offset with respect to the central region 281 of the third proof mass 28c; and
a second pair of bottom driving electrodes 42b, 42d disposed along a line parallel to the y axis, below and laterally offset with respect to the central region 281 of the fourth proof mass 28d.

Referring still to FIG. 7, in order to drive the third and fourth proof masses 28c, 28d 180 degrees out-of-phase with each other using the illustrated configuration illustrated for the second driving electrode assembly 188, the vertically aligned top and bottom driving electrodes located diagonally above and below the third proof mass 28c (e.g., driving electrodes 36d, 41b) are driven in phase with each other but 180 degrees out-of-phase relative to the other electrodes located above and below the third proof mass 28c (e.g., driving electrodes 36b, 41d). Additionally these four electrodes are driven 180 degrees out-of-phase relative to their counterparts on the fourth proof mass 28d (e.g., driving electrodes 37d, 42b, 37b, 42d).

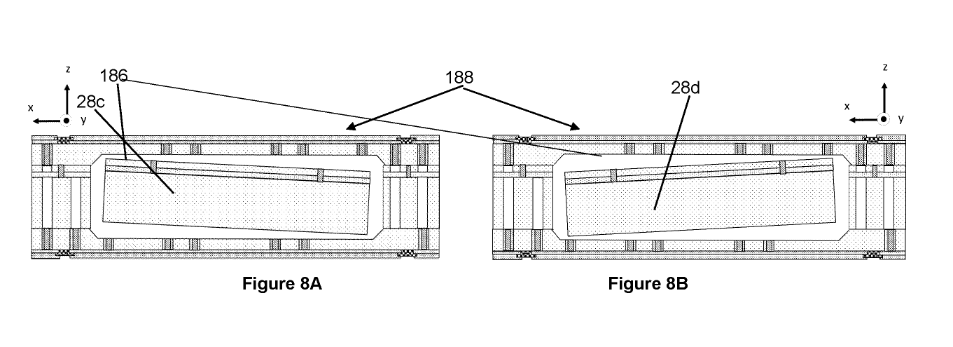

Turning now to FIGS. 8A and 8B, which are cross-sections along lines 8A-8A and 8B-8B in FIG. 1B respectively, the sixth sensing electrode assembly 186 is configured to sense a Coriolis-induced, rocking motion of the third and fourth proof masses 28c, 28d along the x axis, which is indicative of an angular rate Ω_{z} about the z axis. In the illustrated embodiment, the sixth sensing electrode assembly 186 forms fifth and sixth capacitors with the third and fourth proof masses 28c, 28d and measures a difference between a capacitance of the fifth capacitor and a capacitance of the sixth capacitor. The difference is indicative of the angular rate Ω_{z} to be measured. To measure this capacitance difference, the six sensing electrode assembly 186 can include a first pair of top sensing electrodes 36a, 37a disposed along a lines parallel to the x axis, above and laterally offset with respect to central regions 281 of the third and fourth proof masses 28c, 28d. As the third and fourth proof masses 28c, 28d are driven vertically 180 degrees out-of-phase by the second driving electrode assembly 188, their respective Coriolis-induced, rocking motions along the x axis when subjected to angular rate about the z axis will also be 180 degrees out-of phase. In this regard,

FIGS. 8A and 8B depict a snapshot in time of the third and fourth proof masses 28c, 28d, respectively at their maximum amplitude displacement points along the x axis. Therefore, by synchronously measuring the difference in capacitances of electrodes in similar positions on the two masses 28c, 28d (e.g., 36a, 37a) the time-dependent capacitance change due to the angular rate around the z axis is obtained since the angular rate signals (C₀+/−ΔC_{Coriolis}) on the two electrodes are of opposite sign while the static or low-frequency responses due to y and z acceleration (C₀+ΔCₓ+ΔC_{z}), being of the same sign, are subtracted out. Of course, other electrode configurations involving or not differential capacitance measurements can be used in other embodiments. Also, the measurement of the angular rate Ω_{y} can be performed either with matched or nearly matched driving and sensing modes or with unmatched driving and sensing modes.

While the embodiment of the 3-DOF angular rate sensor described above includes four different proof masses, it is possible to build the angular rate sensor with a different number of proof masses. At least one angular rate sensor proof mass is needed, with a set of angular rate sensor electrodes operable to drive the proof mass along one of the x, y and z axes, and sense or detect a rocking motion of the proof mass about a corresponding orthogonal axis, as explained above.

Pressure Sensor

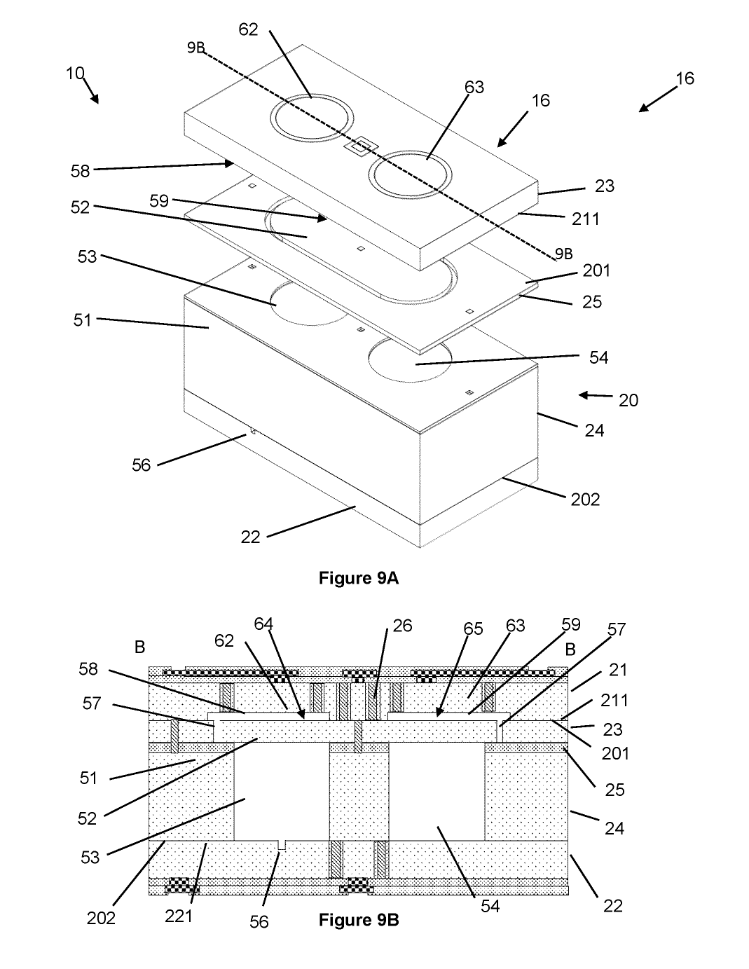

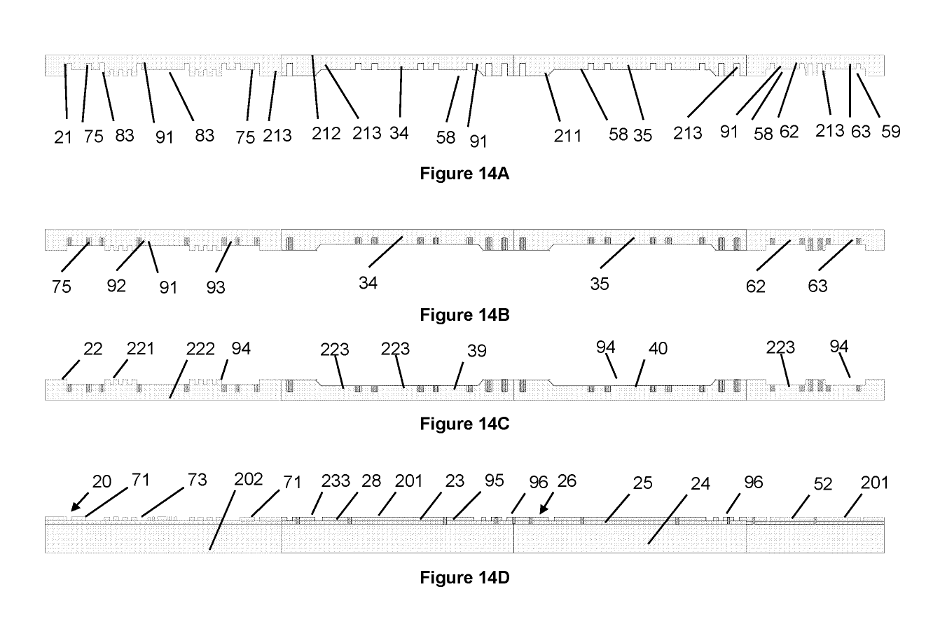

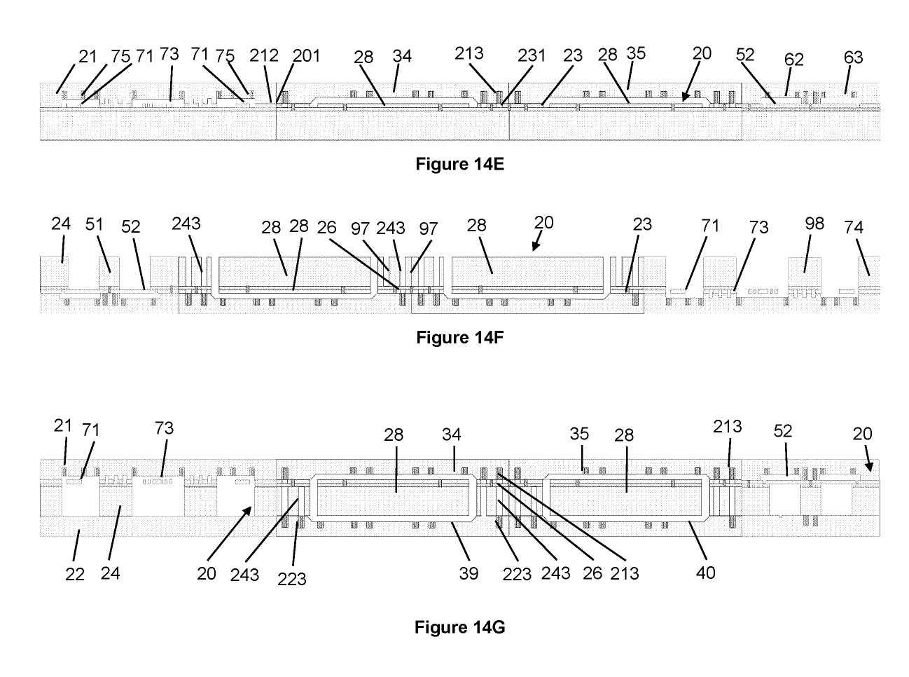

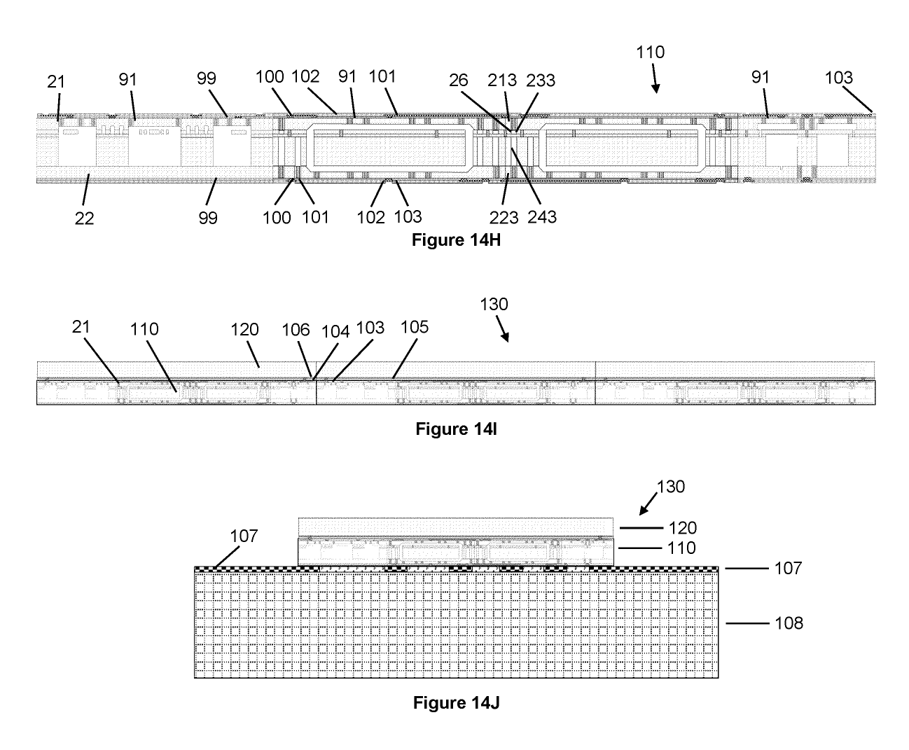

The present invention also provides a MEMS pressure sensor. Referring to FIGS. 9A and 9B (an enlarged view of FIG. 3B), in this embodiment the pressure sensor is a relative pressure sensor 16 which can measure changes in pressure relative to a predefined ambient. At the same time the inertial sensor is formed, the pressure sensor 16 is formed from the multi-wafer stack structure comprising the central MEMS wafer 20 having first and second sides 201, 202, and having formed therein a frame 51 and a membrane 52, the frame defining or outlining at least partially first and second cavities 53, 54. The membrane 52 is suspended over the pressure sensor cavities 53, 54. In other words, during the fabrication process, the different features or elements (electrodes, membranes, frame) of the pressure sensor are formed/patterned in the top, MEMS and bottom wafers during the same process steps as for the features/elements of the inertial sensor, as will become apparent in regard of FIGS. 14A-14I described below.

In this embodiment, the first cavity 53 is connected or in fluid communication with the outside atmosphere of the pressure sensor 16 by means of a vent or channel 56. The membrane 52 is formed in the device layer 23, and the membrane has an outer periphery delimited by a trench 57. The membrane 52 is patterned in the device layer 24 such that it extends beyond and seals each cavity 53, 54. Each cavity 53, 54 is preferably circular to enable drum-like deflection of the membrane over each cavity.

Still referring to FIGS. 9A and B, the multiple layers are assembled to form the MEMS pressure sensor 16 such that the MEMS wafer 20 is surrounded by a first or top cap wafer 21, and a second or bottom cap wafer 22, which are both electrically conductive and made of silicon-based material. As illustrated, the inner side 211 of the top cap wafer 21 is bonded to the first side 201 of the MEMS wafer 20, and the inner side 221 of the bottom cap wafer 22 is bonded to the second side 202 of the MEMS wafer 20. The inner side 211 of the top cap wafer 21 has recesses 58, 59 defining with the membrane 52 capacitance gaps over the first and second cavities 53, 54. The top cap wafer 21 has formed therein top cap electrodes 62, 63 located over the membranes and forming, together with the membrane, capacitors 64, 65 to detect deflection of the membrane 52. In particular, the top cap wafer 21 is bonded to and in electrical contact with the device layer 23 and the bottom cap wafer 22 is bonded to and in electrical in contact with the handle layer 24.

To facilitate electrical connections between the layers, for example between the top cap wafer 21, the MEMS wafer 20 and the bottom cap wafer 22, such layers are preferably bonded using a conductive bond. When so bonded to the MEMS wafer 20, the top cap wafer 21 forms a hermetic vacuum seal with the MEMS wafer 20 to form vacuum gaps 58, 59 between the top cap wafer 21 and the membrane 52 and the bottom cap wafer 22 forms a hermetic seal with the second side 202 of the MEMS wafer 20. Since the vent 56 is provided in the bottom cap wafer 22 and admits ambient pressure from the atmosphere outside the pressure sensor 16 to the cavity 53, the cavity 53 will also be at such an ambient pressure, while the hermetically sealed cavity 54 will remain at the reference pressure at which the sensor was sealed.

The membrane 52 can deflect either upward or downward relative to the pressure sensor electrodes 62, 63 depending upon the relative pressures between each cavity 53, 54 and the top vacuum gaps 58, 59. The difference in capacitance between the measurement capacitor 64 and the reference capacitor 65 is a measure of the differential pressure between the external pressure and the reference. If the reference pressure in cavity 54 is vacuum, the sensor is an absolute pressure sensor. Alternatively, the differential pressure sensor 16 can be used as a relative pressure sensor, if an additional vent similar to 56 is placed in the reference cavity and exposed to a second pressure environment. This may require either providing external tubing or conduits (not shown) to interface the channels as in 56 to the two environments or inserting the pressure sensor 16 at the interface between the two pressure environments.

In other embodiments of the pressure sensor, the pressure sensor membrane can be suspended above a single pressure sensor cavity. It is also possible to form a different number of pressure sensor cavities, depending on the application for which the MEMS sensor chip is to be used.

Magnetic Field Sensor

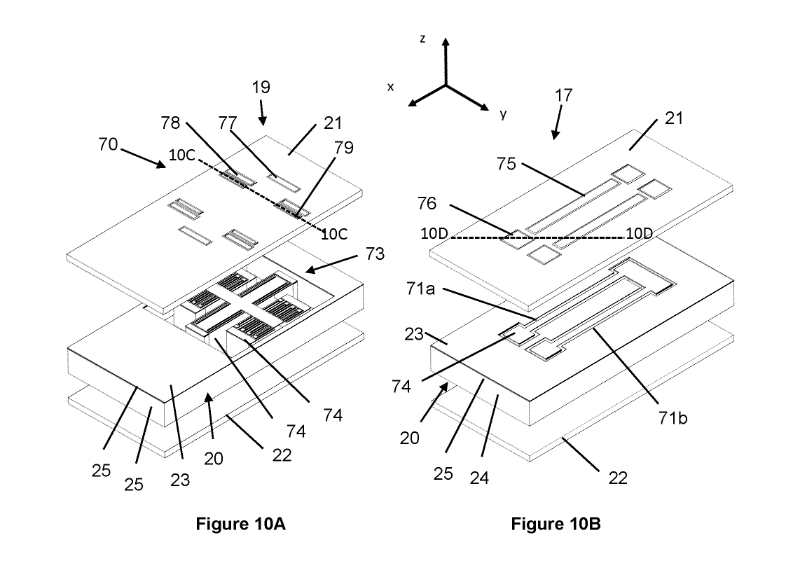

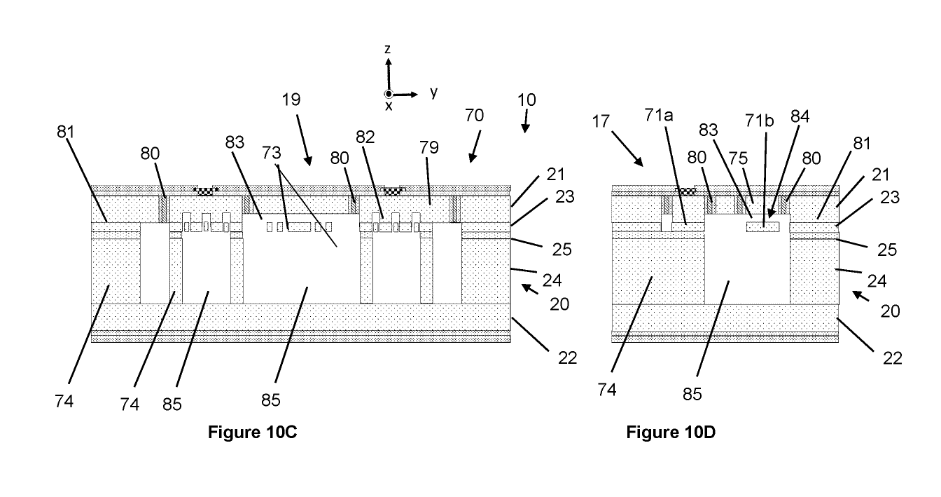

Referring to FIGS. 10A and 10B, exploded isometric views of the Z-axis magnetometer 19 and Y-axis magnetometer 17, and FIGS. 10C and 10D (enlarged views of the cross-sections along 3C and 3D), the present single MEMS chip 10 can also include a MEMS 3-DOF magnetometer or magnetic field sensor 70 integrated therein. In this embodiment, the 3-DOF magnetometer consists of three single axis, or 1 DOF magnetometers 18, 17, 19, which measure the magnetic fields along each of the x, y, and z axes respectively. The x and y magnetometers 18, 17 are identical in structure, so only one 17 is illustrated in FIGS. 10B and 10C. Referring to the partially exploded schematic views in FIG. 10A and FIG. 10B, there are illustrated exemplary embodiments of Z-axis 19 and Y-axis 17 magnetometers respectively. FIGS. 10C and 10D are the Z and Y axis magnetometer cross sections along the lines 10C and 10D in FIG. 1B, The magnetometers 17, 19 include a MEMS wafer 20 provided with magnetic field transducers 71a,b, 73, and support structures 74, a top cap wafer 21 provided with sense electrodes 75 and electrical connections 76, 77, 78, 79, and a bottom cap wafer 22.

In the embodiment illustrated in FIGS. 10A-10D, the magnetic transducers 71 a,b, 73 are fabricated in the device layer 23. The Z-axis magnetic transducer 78 is embodied by a central comb resonator, also referred to as “comb sensor” and “comb structure”.

Also in the illustrated embodiment, the Y-axis magnetic transducers 71a,b are embodied by a pair of resonant membranes 71a, 71b aligned with the x axis. In the illustrated embodiment, the resonant membranes 71a, 71b are long bridges supported at their ends, although other membrane configurations are possible including, but not limited to, square or rectangular membranes supported on more than two points, as well as circular membranes. In addition, in further embodiments, the in-plane (X and Y axes) magnetic transducer 71 a,b, 72a,b need not be embodied by deflectable, resonant membranes, but could be based, for example, on comb structures similar to that used for the out-of-plane (Z axis) magnetic transducer 73. Likewise, in other embodiments, the out-of-plane magnetic transducer 73 need not be embodied by a comb structure, but could be provided, for instance, as vertical strips that are resonant in the x/y plane.

Referring still to FIGS. 10 A-D, the comb resonator 73 and resonant membranes 71a, 71b are supported by, but can be electrically insulated from, posts 74 fabricated in the handle 23 and buried oxide 25 layers. Also, the handle layer 24 and buried oxide 25 are removed from beneath the comb resonators 73 and resonant membranes 71a, 71b elsewhere to allow them to move freely. The dimensions of the resonant membranes 71a, 71b and comb resonator 73 are such that the membranes 71a, 71b move more easily in the vertical direction (i.e., along the thickness of the MEMS magnetometers 17) while the comb resonator 73 moves more easily laterally (i.e., perpendicularly to the thickness of the MEMS magnetometer 19). These components and their operation will be described in more detail below. In FIGS. 10 A-D, the top cap 21 includes electrical connections 76 through which current can be applied to the membranes 71a, 71b, sense electrodes 75 aligned with the membranes 71a, 71b, and electrical connections 77, 78, 79 to the comb resonator 73. The sense electrodes 75 and electrical connections 77, 78, 79 can be isolated from the rest of the top cap 21 by trenches 80 which penetrate the entire thickness of the top cap 21 and which are filled with an insulating material.

Referring to FIGS. 10B and 10C, the top cap 21 is bonded to the MEMS wafer 20, thereby forming a hermetic vacuum seal 81 along the periphery of the chip and establishing electrical contacts 82 between the electrical connections 78, 79 and the comb resonator 73. Recesses 83 are patterned in the top cap 21 which provide gaps 84 between the top cap sense electrodes 75 and the resonant membranes 71a, 71b. A bottom cap 22 is bonded to the bottom of the MEMS wafer 20 to close the

MEMS magnetometer 70 and form one or more hermetic cavities 85, preferably under vacuum.

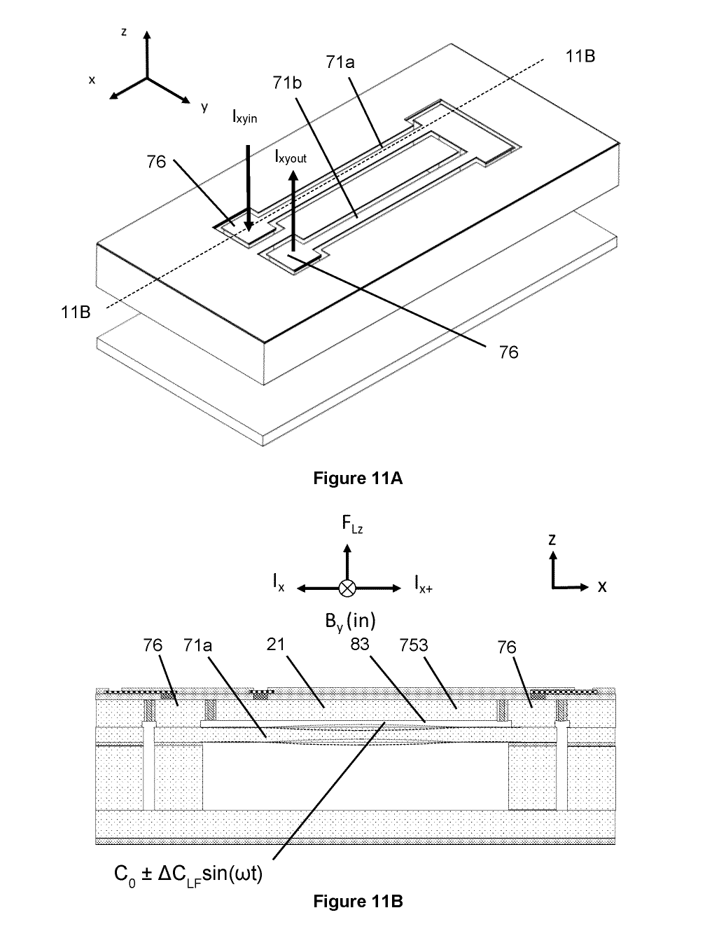

The operation of the y (and x) magnetic sensor is illustrated in FIG. 11A, in which the top cap has been removed, and FIG. 11B, which is a cross section taken along one of the membranes and cap electrodes (section line 11B). FIGS. 11A and B show drive current I_{xyin} injected into one membrane 71a and removed from the other membrane 71 b through two electrical current connections 76. The two membranes 71a, 71b are electrically connected on their opposite ends so that identical current flows in opposite directions through the membranes 71a and 71b). More specifically, in the illustrated embodiment, the current Iₓ flows in opposite direction in the membranes 71a, 71b.

In the illustrated embodiment, the injected current is an alternating current I_{xy}sin(ωt) oscillating at the mechanical resonant frequency w of the membranes, 71a, 71b. In general the magnetic field can point in any direction and the Lorentz force \vec{F_{L}}=I\vec{L}×\vec{B} will be perpendicular to the plane defined by the magnetic field and the injected current in the membranes 71a, 71b. However, since the membranes 71a, 71b can move only in the z direction, they are sensitive to the z component F_{Lz} of the Lorentz force (i.e., their displacement is determined by F_{Lz}). Furthermore, because the Lorentz force is perpendicular to the plane formed by the current and magnetic field vectors, for a current flowing in the x direction, as shown in FIG. 11B, F_{Lz} reacts to the y component B_{y} of the magnetic field. For a given magnetic field B_{y}, the Lorentz force F_{Lz} due to the alternating current Iₓsin(ωt) along the x direction causes the membranes 71 to oscillate at their resonant frequency in the z direction, increasing the sensitivity of the response.

Referring again to FIG. 11B, the top cap 21 can have a gap 83 patterned into it so the resonant membrane 71a and the corresponding top cap electrode 75 form a capacitor. The membrane motion can be monitored by measuring this capacitance, C₀±ΔC_{LF}sin(ωt), where C₀ is the rest capacitance between the membrane 71a and the top cap electrode 75 and ΔC_{LF} is the amplitude of the response to the oscillating Lorentz force. Since the current in the opposing membrane 71b flows in the opposite direction, the two membranes 71a, 71b oscillate 180 degrees out of phase, so the differential capacitance between the two cap electrodes 75 and membranes 71a, 71b is 2ΔC_{LF}sin(ωt). In this way, the sensitivity can be increased by eliminating the static capacitance C₀ and by making the measurement at the membrane mechanical resonant frequency. Because the X-axis magnetometer 18 is identical to the Y-axis magnetometer 17, only rotated by 90 degrees, it will be appreciated that the x component Bₓ of the external magnetic field can be determined in an analogous manner.

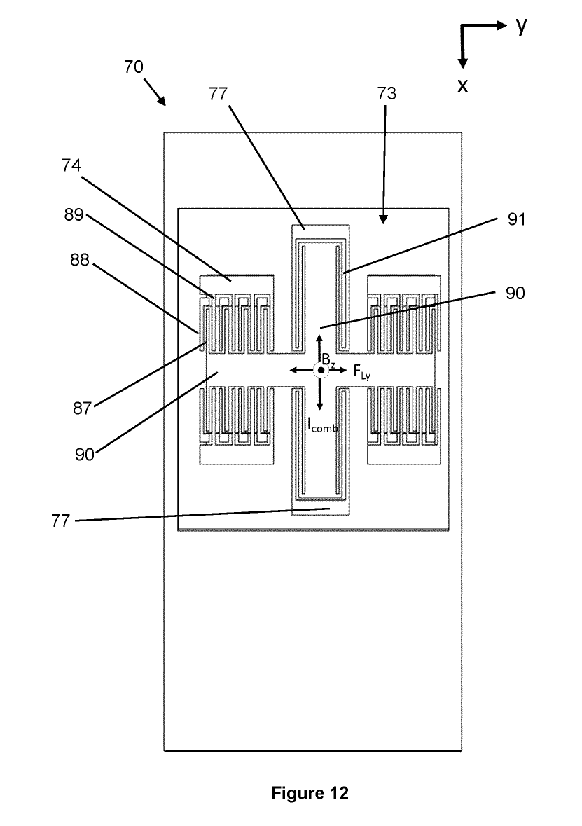

In a planar MEMS device, the drive current is essentially constrained to the plane of the device, so that in order to measure the z component of the magnetic field B_{z}, which is perpendicular to the plane of the device, a transducer structure must be used that responds to the Lorentz force in the plane of the device. To this end, and referring to FIG. 12, the MEMS magnetometer 70 can be provided with a comb resonator or structure 73 provided with three sets of interdigitated fingers 87, 88, 89 and including a static portion or frame 74 supporting the stationary sets of fingers 88, and 89 and a movable portion or shuttle 90 supporting the movable set of fingers 87. The comb resonator 73 may advantageously provide a larger sensing capacitance area in the plane of the device than simpler beam structures.

In the illustrated embodiment, the shuttle 90 is suspended from folded springs 91 that enable it to move laterally. An oscillating current I_{comb}sinωt is injected at the spring supports 77 and runs through the springs 91 and down a central beam of the shuttle 90, which extends along the x direction in FIG. 12. This x-directed oscillating current in the shuttle 90 interacts with 6, to produce an oscillating Lorentz force F_{Ly} in the y direction perpendicular to the central beam of the shuttle 90. The resulting lateral oscillation of the shuttle 90 is detected by measuring the capacitance between comb fingers 87 on the cross-member of the shuttle 90 and two sets of stationary comb fingers 88, 89 on the frame 74.

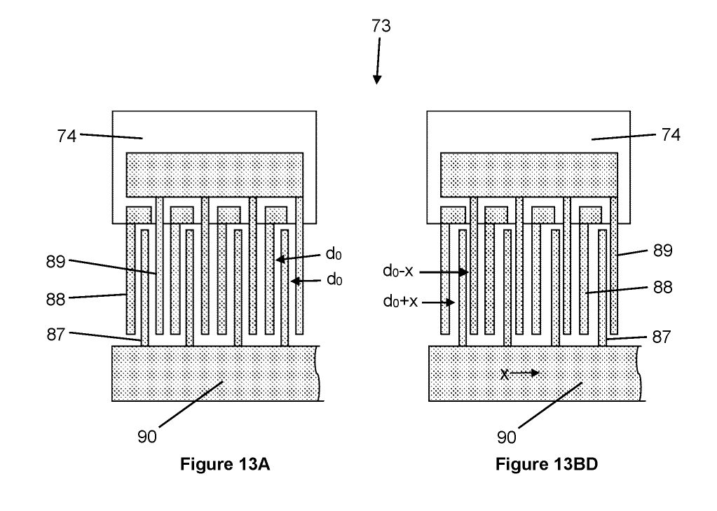

FIGS. 13A and 13B are details of the comb sensor 73. Referring to FIG. 13A, in the absence of an external magnetic field the comb fingers 87 on the shuttle 90 are positioned an equal distance d between the comb fingers 88 on a first set of the frame 74 and the comb fingers 89 on a second set of the frame 74, so that the capacitance C₀ between each of the shuttle fingers 87 and each of the fingers of the first and second set of fingers 88, 89 surrounding it is the same. Referring to FIG. 13B, when the shuttle 90 translates laterally (here by x) in response to the Lorentz force, the capacitance between each of the shuttle fingers 87 and the adjacent finger 88 of the second set increases to a linear approximation by C₀x/d while the capacitance between each shuttle finger 87 and the adjacent finger 89 of the first set decreases by the same amount. Thus, the differential capacitance change due to the magnetic field between the two capacitors is approximately 2C₀x/d.

Referring back to FIGS. 10A and 10B, the comb fingers 88, 89 on each set of the frame 74 combs are connected through electrical contacts 82 to connections 78, 79 in the top cap 21 so all the comb capacitances can be measured in parallel. Thus the measured capacitance, from which B_{z} can be determined, can be magnified by the number of comb fingers as well as by the resonance gain due to using a drive current whose oscillating frequency matches or nearly matches the mechanical resonance frequency of the shuttle 90.

It should be noted that in the embodiment described above, each of the first, second and third magnetic field transducers is a Lorentz-force-based transducer that relies on the mechanical motion of a current-carrying conductor due to the Lorentz force acting on the current-carrying conductor in the present of an external magnetic field. However, in other embodiments, the MEMS magnetometer could be based on other approaches for magnetic sensing including, for example, AMR and Hall Effect.

It should also be noted that while the embodiment described above provides a three-axis MEMS magnetometer, in other embodiments, a single-axis or a two-axis MEMS magnetometer having a similar stacked 3D wafer structure could also be implemented without departing from the scope of the present invention.

Other Multiple-DOF Embodiments The embodiment of a MDOF sensor described above is a 10 DOF sensor (3 DOF accelerometer, 3 DOF angular rate sensor, 1 DOF pressure sensor, 3 DOF magnetometer). In many applications a full complement of 10 degrees of freedom may not be required. Alternatively, if high accuracy through sensor fusion is not required, reduction in sensor area, and hence cost, can be obtained by omitting unnecessary degrees of freedom.

Of course, 1, 2, and 3 DOF sensors for each of the measurands (acceleration, angular rate, magnetic field, and pressure) are possible with this architecture. However, the real advantages come from combining different sensors in a single self-packaged integrated MDOF sensor. Some MDOF sensors of particular interest are described below.

9 DOF Sensor

For many land-based navigational applications where altitude changes are of less or little interest, 9 degrees of freedom will suffice. In this case the pressure sensor can be omitted, along with any related electrical circuitry. Because the pressure sensor is small, little silicon area will be saved.

7 DOF Sensor

Some applications may require additional accuracy in the vertical or z axis. For example navigation in multi-floor buildings and Unmanned Air Vehicles (UAVs) require good altitude information. For these applications the 6 DOF inertial sensor can be augmented with a pressure sensor that provides altitude information by measuring changes in barometric pressure. This 7 DOF sensor would be similar to the described 10 DOF sensor but without the magnetometers. The magnetometers take up little area in the MEMS compared to the proof masses, but the IC can be simplified by leaving out the magnetometer sense electronics.

Low Power Synthetic Gyroscope (9 DOF)

For applications such as gaming, or gesture-based controls, high resolution angular rate measurements are not required. Instead only gross detection of rotation and translation are needed. Furthermore, for these applications low power is desirable. It is possible to produce a low power synthetic gyroscope using only a 3 DOF accelerometer and a 3 DOF magnetometer. The magnetometer is used to measure attitude and angular change relative to the earth's magnetic field, providing a low resolution gyroscope function. This information fused with accelerometer data provides adequate position, velocity, attitude, and angular rate information for low accuracy requirement applications. Eliminating the angular rate inertial sensors as well as the pressure sensor provides substantial savings in chip area, cost, and power consumption.

Method For Manufacturing A Multi-DOF Mems Sensor

In accordance with another aspect, there is provided a method of manufacturing a MEMS MDOF sensor. The method for manufacturing the MEMS device will be described with reference to the diagrams of FIGS. 14A to 14P, which schematically illustrate steps of an exemplary embodiment. It will be understood, however, that there is no intent to limit the method to this embodiment, for the method may admit to other equally effective embodiments. It will also be understood that the manufacturing method can, by way of example, be performed to fabricate multi-DOF MEMS sensors like those described above with reference to FIGS. 1 to 13, or any other suitable MEMS sensor provided with a plurality of sensing transducers.

Referring to FIGS. 14A to 14H, there are schematically illustrated fabrication steps of an exemplary embodiment of the method for manufacturing a multi-mass MEMS motion sensor. The figures are the combined cross-sections of FIGS. 3A, 3B, and 3C, which in turn are cross-sections along lines AA, BB, CC, and DD in FIG. 1B. The cross sections are combined to illustrate the progression of each sensor type through a common fabrication flow.

Referring to FIG. 14A, the manufacturing method includes a step of providing a top cap wafer 21. The top cap wafer 21 has opposed inner and outer sides 211, 212 and is made of an electrically conductive semiconductor material such as, for example, a silicon-based semiconductor. In some embodiments, the step of providing the top cap wafer 21 can include a step of forming recesses 58, 59, 83, or capacitor gaps, by removing top cap wafer material from a central region of the inner side 211 of the top cap wafer 21. The recesses 58, 59, 83 can be formed by any of several manufacturing methods including, but not limited to, photolithography and etch or patterned oxidation and etch. The recesses 58, 59, 83 may eventually form part of cavities whose role is to form a capacitor gaps for proof masses, pressure sensor membranes, and magnetometer transducers once the top cap wafer 21 is bonded to a MEMS wafer 20, as described below. The manufacturing method also includes a step of forming top electrodes 34-38, 62, 63, 75 and insulated conducting cap wafer channels 213 from the inner side 211 into the top cap wafer 21, which can include patterning trenches 91 into the top cap wafer 21.

Turning to FIG. 14B, the trenches 91 may be filled with an insulating material 92. Alternatively, the trenches 91 may be lined with an insulating material 92 and then filled with a conducting material 93. For this purpose, trench and fill processes are available at different MEMS fabrication facilities, and the insulating and conducting materials may vary between them.

Referring to FIG. 14C, the steps of FIGS. 14A and 14B may be repeated on a bottom cap wafer 22, which has opposed inner and outer sides 221, 222 to form a pattern of bottom cap electrodes 39-43, as well as recesses 94 or capacitor gaps, and insulated conducting cap wafer channels 223. As for the top cap wafer 21, the bottom cap wafer 22 is made of an electrically conductive semiconductor material such as, for example, a silicon-based semiconductor.

Referring now to FIG. 14D, the manufacturing method next includes providing a MEMS wafer 20 having opposed top and bottoms sides 201, 202. In FIG. 14D, the MEMS wafer is a SOI wafer including a device layer 23, a handle layer 24, and an insulating layer 25 (e.g., buried oxide) sandwiched between the device layer 23 and the handle layer 24. Conducting shunts 26 are formed between the device layer 23 and the handle layer 24 through the insulating layer 25. The conducting vias 26 are patterned at desired spots on the device layer 23 and etched through the device layer 23 and insulating layer 25 to or slightly into the handle layer 24. The conducting shunts 26 may then be filled with a conducting material 95 which can be doped polycrystalline silicon (polysilicon), a metal, or another suitable conducting material. In this way an electrical path is formed vertically between the device layer 23 and the handle layers 24 of the MEMS wafer 20. Finally, the MEMS patterns including inertial springs 29, supports, 27 proof masses 28, feedthroughs 233, pressure membrane 52, magnetometer membranes 71, 72, and magnetometer comb structures 73 may be patterned, delimited by trenches 96 in the device layer 23.

Referring to FIG. 14E, the manufacturing method includes a step of aligning and bonding the top side 201 of the MEMS wafer 20 to the inner side 212 of the top cap wafer 21. This step can involve aligning the feedthroughs 231 in the device layer 23 to corresponding insulated conducting cap wafer channels 213 on the top cap wafer 21, and aligning the electrodes 34-38, 62, 63, 75 in the top cap wafer 21 to corresponding electrodes 71, 72, 73, 28, 52 on the MEMS wafer 20. Advantageously, the wafer bonding process used can provide a conductive bond such as, for example, fusion bonding, gold thermocompression bonding, or gold-silicon eutectic bonding.

Referring to FIG. 14F, the manufacturing method next includes patterning the handle layer 24 of the MEMS wafer 20 with MEMS structures such as a plurality of proof masses 28a-e, supports 51, 74, and feedthroughs 243, which are aligned with similar structures on the device layer 23, such as the electrodes 71, 72, 73, 28, 52 and flexible springs (not visible in the cross section). Trenches 97 can be etched around each feedthrough 243 to isolate the feedthrough 243 from the rest of the handle layer 24. In some embodiments, if the feedthrough 243 is attached to a SOI via 26 on the device layer 23, then the feedthrough 243 becomes an isolated electrical feedthrough. However, if the feedthrough 243 is not attached to a SOI via, the feedthrough 243 then acts merely as a mechanical support 98.

Referring to FIG. 14G, the bottom cap wafer 22 may next be bonded to the backside of the handle layer 24. Again, a wafer bonding method such as fusion bonding, gold thermocompression bonding, or gold-silicon eutectic bonding can be used to provide electrical contacts between the feedthroughs 243 in the MEMS wafer 20 and pads 223 in the bottom cap wafer 22, which are connected electrically to the bottom electrodes 39-43. In this manner, a conductive path can be provided from the bottom electrodes 39-43 through the bottom cap pads 223, handle feedthroughs 243, SOI vias 26, and SOI device layer pads 233 to the top cap pads 213.

Still referring to FIG. 14G, at this stage of the manufacturing method, the MEMS wafer 20 is hermetically sealed between the top and bottom cap wafers 21, 22 and the MEMS transducer elements (masses 28, membranes 52, 71, 72, and comb transducer 73) are aligned with the top cap and bottom cap electrodes 34-43, 62, 63, 75. Because the insulating conducting pathways 213, 223 do not yet fully penetrate the caps, the electrodes on each cap are shorted together through the remaining silicon. Now referring to FIG. 14H, both cap wafers 21, 22 may then be thinned, for example by grinding and polishing, to expose the insulating conducting channels 91. The electrodes are thus electrically isolated except for connections to top cap or bottom cap pads through the feedthroughs 213, 223, 233, 243 and conducting vias 26. Both outer surfaces of the top and bottom cap wafers 21, 22 can be passivated with an insulating oxide layer 99 for protection purposes.

Still referring to FIG. 14H, contacts 100 can be opened in the protective oxide 99 over the pads in the top cap wafer 21, bond pad metal 101 can be deposited and patterned, and passivating oxide 102 can be applied and patterned to expose the bond pads 103. These or similar steps may be performed on the bottom cap wafer 22. In this way, electrical connections from the top and bottom inertial sensor electrodes, pressure sensor membrane and electrodes, and magnetometer transducers can become accessible from the top or bottom for wire bonding, flip chip bonding, or wafer bonding. After completion of the step depicted in FIG. 14H, the wafer level fabrication of the hermetically sealed 3DS MEMS MDOF sensor wafer 110 is obtained.

At this point, if desired, the MEMS MDOF wafer 110 can be diced into individual MEMS chips. Alternatively, the architecture described herein may allow a wafer containing ICs for sensing and data processing to be bonded directly to the MEMS MDOF sensor wafer 110. The wafer-level integration of the 3D system (3DS) can involve bonding of an application-specific IC (ASIC) wafer designed with the appropriate system electronics for the application and with a physical bond pad layout commensurate with the MEMS MDOF sensor wafer 110.

Referring to FIG. 141, bump-bonds 104 can be applied to one side of the MEMS MDOF sensor wafer 110. Numerous approaches and materials used in the semiconductor industry can provide wafer bumps. In one embodiment, a thick photoresist underfill 105 is applied to one side (e.g., the top cap wafer 21 in FIG. 141) of the MEMS MDOF sensor wafer 110 and patterned to produce an electroplating mask with openings over the bond pad metal 103. Thick solder can be electroplated into the openings. The solder can be left as a column or reflowed into balls, depending upon the bonding method. The photoresist can be stripped leaving the balls isolated, or can be left in place as an underfill to protect the wafer surface. If the photoresist is removed, a separate polymeric underfill layer 105 can be coated and patterned around the solder balls. The purpose of the underfill is to protect the wafer or chip surface and to mitigate bump shearing due to the thermal stress of heating during bonding.

Still referring to FIG. 141, an ASIC wafer 120 can then be flipped and aligned to the MEMS MDOF sensor wafer 110 (e.g., to the top cap wafer 21) such that ASIC bond pads 106 are aligned to the top cap solder bumps 104. The ASIC wafer has circuitry electrically connected to the MEMS MDOF sensor wafer 110. The ASIC wafer 120 may be bonded to the MEMS motion sensor wafer 110 using temperature and pressure to produce a 3DS wafer 130. At this point the ASIC wafer 120 (e.g., a CMOS wafer) can be thinned, if desired, and passivated with a PECVD oxide. The bonded 3DS wafer 130 can finally be diced into individual 3DS components.

Referring to FIG. 14J, in some embodiments, the 3DS wafer 130 can be diced into self-packaged MEMS IMUs and be directly solder bumped to leads 107 on a PCB 108 without requiring additional wire bonding or external packaging.

Of course, numerous modifications could be made to the embodiments described above without departing from the scope of the present invention.

1. A single Micro-Electro-Mechanical System (MEMS) sensor chip for measuring multiple parameters, referred to as multiple degrees of freedom (DOF), the sensor chip comprising:
an electrically conductive MEMS wafer having first and second sides and an outer frame;
an electrically conductive top cap wafer having an inner top cap side and an outer top cap side, the inner top cap side being bonded to the first side of the MEMS wafer;
an electrically conductive bottom cap wafer having an inner bottom cap side and an outer bottom cap side, the inner bottom cap side being bonded to the second side of the MEMS wafer,
at least one of the outer top cap side and the outer bottom cap side comprising electrical connections;
at least two distinct sensors, each patterned in the electrically conductive MEMS wafer and in at least one of the top and bottom cap wafer, said sensors being operative to sense at least two distinct parameters, respectively, along at least one of mutually orthogonal X, Y and Z axes; and
insulated conducting pathways extending from said electrical connections, through at least one of the electrically conductive top cap and bottom cap wafers, and through the electrically conductive MEMS wafer, to said sensors, for conducting electrical signals between said sensors and the electrical connections, said sensors being enclosed by the electrically conductive top and bottom cap wafers and by the outer frame of the electrically conductive MEMS wafer.

2. The single MEMS sensor chip according to claim 1, wherein at least one of said sensors is hermetically sealed within said electrically conductive top and bottom cap wafers and by the electrically conducting MEMS wafer.

3. The single MEMS sensor chip according to claim 1, wherein one of said sensors is a pressure sensor.

4. The single MEMS sensor chip according to claim 1, wherein one of said sensors is 3-DOF magnetometer.

5. The single MEMS sensor chip according to claim 1, wherein one of said sensors is an inertial sensor including at least one bulk proof mass suspended in a cavity by flexible springs patterned in the electrically conductive MEMS wafer, the flexible springs enabling the bulk proof mass to move relative to the outer frame along the x, y and x axes, the cavity being defined by the inner top cap side and by the inner bottom cap side of the electrically conductive top and bottom cap wafers, and by sidewalls patterned in the electrically conductive MEMS wafer.

6. The single MEMS sensor chip according to claim 5, wherein said inertial sensor comprises a 3-DOF accelerometer and one of said at least two distinct parameters is an acceleration of the MEMS sensor chip, wherein the at least one bulk proof mass comprises an accelerometer proof mass, the 3-DOF accelerometer comprising accelerometer electrodes patterned in at least one of the electrically conductive top and bottom cap wafers, the accelerometer electrodes facing the accelerometer proof mass and being operable to detect a translational motion of the accelerometer proof mass, indicative of the acceleration of the MEMS sensor chip along the X, Y and Z axes.

7. The single MEMS sensor chip according to claim 5, wherein said inertial sensor comprises a 3 DOF angular rate sensor and one of said at least two distinct parameters is an angular rate of the MEMS sensor chip; wherein the at least one bulk proof mass comprises at least one angular rate sensor proof mass, suspended in a corresponding angular rate cavity; the 3-DOF angular rate sensor comprising angular rate sensor electrodes patterned in at least one of the electrically conductive top and bottom cap wafers, the angular rate sensor electrodes facing the angular rate sensor proof mass and being operable to drive the angular rate proof mass and to detect a rocking motion of the angular rate sensor proof mass, indicative of the angular rate of the MEMS sensor chip about the X, Y and Z axes.

8. The single MEMS sensor chip according to claim 5, wherein one of said sensors is a pressure sensor and one of said parameters is a pressure, said pressure sensor comprising:
a pressure sensor membrane patterned in the MEMS wafer and suspended over at least one pressure sensor cavity, and
one or more pressure sensor electrode(s) patterned in at least one of the electrically conductive top and bottom cap wafers and facing pressure sensor membrane, the pressure sensor electrode(s) being operable to detect a deflection of said pressure sensor membrane, indicative of a variation of the pressure in the MEMS sensor chip.

9. The single MEMS sensor chip according to claim 5, wherein one of said sensors is a 3-DOF magnetometer, and one of said parameters is a magnetic field, the 3DOF magnetometer comprising:
two in-plane or X and Y magnetometers including:
resonant membranes, patterned in the MEMS wafer and aligned with the X and Y axis respectively; and
magnetometer electrodes associated with the resonant membranes and patterned in one of the electrically conductive top and bottom cap wafers, the magnetometer electrodes being operatively coupled to the resonant membranes, to detect motion of resonant membranes along the Z axis, indicative of a component of a magnetic field along the X or Y axis; and
one out-of-plane or Z magnetometer, including:
a comb structure patterned in the MEMS wafer, to detect a motion of the comb sensor along one of the X or Y axis, indicative of a component of a magnetic field along the Z axis,
whereby in use, alternating current is injected in the X, Y and Z magnetometers, a Lorentz force acting on the resonant membranes and/or comb structure in response to the magnetic field (\vec{F_{L}}=I\vec{L}×\vec{B}).

10. The single MEMS sensor chip according to claim 1, wherein the electrically conductive MEMS, top cap and bottom cap wafers are made of an electrically conductive silicon-based semiconductor material.

11. The single MEMS sensor chip according to claim 1, wherein the electrically conductive MEMS wafer is a silicon-on-insulator (SOI) wafer, said SOI wafer including a device layer, a handle layer, and an insulating layer sandwiched between the device and handle layers.

12. The single MEMS sensor chip according to claim 1, wherein at least one of the electrically conductive top cap and bottom cap wafers is an SOI wafer.

13. The single MEMS sensor chip according to claims 5, wherein the pressure of said cavity of the inertial sensor is under vacuum.

14. The single MEMS sensor chip according to claim 6, wherein the at least one angular rate sensor proof mass comprises four different angular rate proof masses, each suspended in corresponding angular rate sensor cavities.

15. The single MEMS sensor chip according to claim 8, wherein the at least one pressure sensor cavity comprises first and second pressure sensor cavities, the first pressure sensor cavity being in fluid communication with an outside atmosphere via a vent, and the second pressure sensor cavity being at a predetermined pressure.

16. The single MEMS sensor chip according to claim 8, wherein the at least one pressure sensor cavity is circular, enabling a drum-like deflection of the pressure sensor membrane over its corresponding cavity.

17. The single MEMS sensor chip according to claim 9, wherein the resonant membranes of the 3-DOF magnetometer includes longitudinal strips.

18. The single MEMS sensor chip according to claim 9, wherein the electrically conductive MEMS wafer is an SOI wafer comprising a handle layer and device layer, the resonant membranes and the comb structure are patterned in the device layer of the electrically conductive MEMS wafer, the resonant membranes and the comb structure being suspended over magnetometer cavities etched in the handle layers.

19. The single MEMS sensor chip according to claim 8, wherein the conductive MEMS wafer is an SOI wafer comprising a handle layer and device layer, the pressure sensor membrane are patterned in the device layer of the electrically conductive MEMS wafer, the pressure sensor membrane being suspended over the pressure sensor cavity etched in the handle layer.

20. The single MEMS sensor chip according to claim 1, wherein at least some of the insulated conducting pathways extend through the thickness of the electrically conductive top cap, MEMS or bottom cap wafers and have sidewalls coated with an insulating material, said channel being filled with a conducting material.

21. The single MEMS sensor chip according to claim 1, wherein each of said at least two distinct sensors comprises electrodes patterned on the inner side of the electrically conductive top and bottom cap wafers and in the electrically conductive MEMS wafer, the electrodes being delineated by trenches filled with an insulating material.

22. The single MEMS sensor chip according to claim 21, wherein each of said electrodes is connected to one of said electrical connections by way of a corresponding one of the insulating conducting pathways.

23. The single MEMS sensor chip according to claim 1, said single MEMS sensor chip being a 10-DOF sensor chip wherein said at least two distinct sensors comprises a 3-DOF accelerometer, a 3-DOF angular rate sensor, a 1-DOF pressure sensor and a 3-DOF magnetometer.

24. The single MEMS sensor chip according to claim 1, said single MEMS sensor chip being a 9-DOF sensor chip wherein said at least two distinct sensors comprises a 3-DOF accelerometer, a 3-DOF angular rate sensor and a 3-DOF magnetometer.

25. The single MEMS sensor chip according to claim 1, said single MEMS sensor chip being a 7-DOF sensor chip wherein said at least two distinct sensors comprises a 3-DOF accelerometer; a 3-DOF angular rate sensor, and a pressure sensor.
